(19) United States
(12) Patent Application Publication
(10) Pub. No.: US 2022/0035235 A1
(43) Pub. Date: Feb. 3, 2022

(54) MASK BLANK, TRANSFER MASK, AND SEMICONDUCTOR-DEVICE MANUFACTURING METHOD

(71) Applicant: HOYA CORPORATION, Tokyo (JP)

(72) Inventors: Ryo OHKUBO, Tokyo (JP); Hitoshi MAEDA, Tokyo (JP); Keishi AKIYAMA, Tokyo (JP); Osamu NOZAWA, Tokyo (JP)

(73) Assignee: HOYA CORPORATION, Tokyo (JP)

(21) Appl. No.: 17/275,628

(22) PCT Filed: Sep. 10, 2019
(86) PCT No.: PCT/JP2019/035483

§ 371 Date: Mar. 11, 2021

(30) Foreign Application Priority Data
Sep. 25, 2018 (JP) 2018-178888

(51) Int. Cl. G03F 1/32; G03F 1/34; G03F 1/54; C23C 14/08; C23C 14/34; H01L 21/027

(52) U.S. Cl. CPC G03F 1/32; G03F 1/34; G03F 1/54; H01L 21/0274; C23C 14/081; C23C 14/34; C23C 14/083

(57) ABSTRACT

Provided is a mask blank including an etching stopper film. The mask blank has a structure where an etching stopper film and a thin film for pattern formation are stacked in this order on a transparent substrate, featured in that the thin film includes a material containing silicon, the etching stopper film includes a material containing hafnium, aluminum, and oxygen, and a ratio by atom % of an amount of hafnium to a total amount of hafnium and aluminum in the etching stopper film is 0.86 or less.

### CROSS-REFERENCE TO RELATED APPLICATIONS

This application is a National Stage of International Application No. PCT/JP2019/035483, filed Sep. 10, 2019, which claims priority to Japanese Patent Application No. 2018-178888, filed Sep. 25, 2018, and the contents of which is incorporated by reference.

### TECHNICAL FIELD

This disclosure relates to a mask blank, and a transfer mask manufactured using the mask blank. Further, this disclosure relates to a method of manufacturing a semiconductor device using the transfer mask.

### BACKGROUND ART

Generally, in a manufacturing process of a semiconductor device, photolithography is used to form a fine pattern. In forming this pattern, multiple transfer masks are usually used; and particularly in forming a fine pattern, a phase shift mask with an enhanced transfer performance, mainly resolution, by using phase difference is often used. Further, in order to miniaturize a pattern of a semiconductor device, in addition to improvement and enhancement of a transfer mask represented by a phase shift mask, it is necessary to shorten a wavelength of an exposure light source used in photolithography. Thus, shortening of wavelength has been advancing recently from the use of KrF excimer laser (wavelength 248 nm) to ArF excimer laser (wavelength 193 nm) as an exposure light source used in the manufacture of a semiconductor device.

A transfer mask including a transparent substrate and a thin film for pattern formation including a silicon-based material is known as an aspect of a transfer mask. In a thin film for pattern formation including a silicon-based material, a thin film pattern is generally formed by dry etching with fluorine-based gas as etching gas. However, etching selectivity of dry etching with fluorine-based gas of a thin film for pattern formation including a silicon-based material is not as high between a substrate including glass materials. In Patent Document 1, an etching stopper film including Al₂O₃, etc., which is a material with high durability to dry etching of fluorine-based gas, is intervened between a substrate and a phase shift film. Such a configuration can prevent digging into a surface of a substrate when forming a phase shift pattern in a phase shift film by dry etching with fluorine-based gas. Further, Patent Document 2 describes the use of hafnium oxide for the material of an etching stopper film, as an Al₂O₃ film lacks chemical stability and easily dissolves in acid used in a cleaning process of a photomask. Moreover, Patent Document 3 provides an etching stopper film including a mixture of Al₂O₃ and MgO, ZrO, Ta₂O₃, or HfO on a surface of a substrate.

### PRIOR ART PUBLICATIONS

### Patent Documents

### Patent Document 1

Japanese Patent Application Publication 2005-208660

### Patent Document 2

Japanese Patent Application Publication H07-36176

### Patent Document 3

Japan Patent No. 3210705

### SUMMARY OF THE DISCLOSURE

### Problems to be Solved by the Disclosure

A transmittance to an exposure light of a hafnium oxide film is lower than that of a silicon oxide film and an aluminum oxide film. Particularly, a hafnium oxide film has a low transmittance to an exposure light of an ArF excimer laser (wavelength: about 193 nm) (hereinafter referred to as ArF exposure light). Therefore, in the case where hafnium oxide is used in an etching stopper film of a transfer mask to which an ArF exposure light is applied, there was a problem of the necessity to increase the amount of an exposure light, causing reduction in throughput of an exposure light transfer step in the manufacture of a semiconductor device.

An aluminum oxide film has a significantly high transmittance to an ArF exposure light compared to a hafnium oxide film. Further, an aluminum oxide film has high etching durability to dry etching using fluorine-based gas. Therefore, an etching stopper film formed of a mixture of hafnium oxide and aluminum oxide was considered capable of achieving both high etching durability to dry etching using fluorine-based gas and a high transmittance to an ArF exposure light. However, it was found that an etching stopper film formed of a mixture of hafnium oxide and aluminum oxide has a lower transmittance to an ArF exposure light than a hafnium oxide film depending on mixture ratio.

This disclosure was made to solve the conventional problem described above. Namely, an aspect of this disclosure is to provide a mask blank having a structure where an etching stopper film and a thin film for pattern formation are stacked in this order on a transparent substrate, the etching stopper film having high durability to dry etching with fluorine-based gas used in patterning a thin film for pattern formation, further having a high transmittance to an exposure light. A further aspect is to provide a transfer mask manufactured using this mask blank. Moreover, an aspect of this disclosure is to provide a method of manufacturing a semiconductor device using the transfer mask.

### Means for Solving the Problem

For solving the above problem, this disclosure includes the following configurations.

### (Configuration 1)

A mask blank having a structure where a transparent substrate has stacked thereon an etching stopper film and a thin film for pattern formation in this order,

in which the thin film includes a material containing silicon,

in which the etching stopper film includes a material containing hafnium, aluminum, and oxygen, and

in which a ratio by atom % of an amount of the hafnium to a total amount of the hafnium and the aluminum in the etching stopper film is 0.86 or less.

### (Configuration 2)

The mask blank according to Configuration 1, in which a ratio by atom % of an amount of the hafnium to a total amount of the hafnium and the aluminum in the etching stopper film is 0.60 or more.

### (Configuration 3)

The mask blank according to Configuration 1 or 2, in which an oxygen content of the etching stopper film is 60 atom % or more.

### (Configuration 4)

The mask blank according to any of Configurations 1 to 3, in which the etching stopper film has an amorphous structure in a state including a bond of hafnium and oxygen and a bond of aluminum and oxygen.

### (Configuration 5)

The mask blank according to any of Configurations 1 to 4, in which the etching stopper film consists of hafnium, aluminum, and oxygen.

### (Configuration 6)

The mask blank according to any of Configurations 1 to 5, in which the etching stopper film is formed in contact with a main surface of the transparent substrate.

### (Configuration 7)

The mask blank according to any of Configurations 1 to 6, in which the etching stopper film has a thickness of 2 nm or more.

### (Configuration 8)

The mask blank according to any of Configurations 1 to 7, in which the thin film is a phase shift film, having a function to generate a phase difference of 150 degrees or more and 210 degrees or less between an exposure light that transmitted through the phase shift film and an exposure light that transmitted through air for a same distance as a thickness of the phase shift film.

### (Configuration 9)

The mask blank according to Configuration 8, in which a light shielding film is provided on the phase shift film.

### (Configuration 10)

The mask blank according to Configuration 9, in which the light shielding film includes a material containing chromium.

### (Configuration 11)

A transfer mask having a structure where a transparent substrate has stacked thereon an etching stopper film and a thin film having a transfer pattern in this order,

in which the thin film includes a material containing silicon,

in which the etching stopper film includes a material containing hafnium, aluminum, and oxygen, and

in which a ratio by atom % of an amount of the hafnium to a total amount of the hafnium and the aluminum in the etching stopper film is 0.86 or less.

### (Configuration 12)

The transfer mask according to Configuration 11, in which a ratio by atom % of an amount of the hafnium to a total amount of the hafnium and the aluminum in the etching stopper film is 0.60 or more.

### (Configuration 13)

The transfer mask according to Configuration 11 or 12, in which an oxygen content of the etching stopper film is 60 atom % or more.

### (Configuration 14)

The transfer mask according to any of Configurations 11 to 13, in which the etching stopper film has an amorphous structure in a state including a bond of hafnium and oxygen and a bond of aluminum and oxygen.

### (Configuration 15)

The transfer mask according to any of Configurations 11 to 14, in which the etching stopper film consists of hafnium, aluminum, and oxygen.

### (Configuration 16)

The transfer mask according to any of Configurations 11 to 15, in which the etching stopper film is formed in contact with a main surface of the transparent substrate.

### (Configuration 17)

The transfer mask according to any of Configurations 11 to 16, in which the etching stopper film has a thickness of 2 nm or more.

### (Configuration 18)

The transfer mask according to any of Configurations 11 to 17, in which the thin film is a phase shift film, the phase shift film having a function to generate a phase difference of 150 degrees or more and 210 degrees or less between an exposure light that transmitted through the phase shift film and an exposure light that transmitted through air for a same distance as a thickness of the phase shift film.

### (Configuration 19)

The transfer mask according to Configuration 18 including a light shielding film having a light shielding pattern with a light shielding band on the phase shift film.

### (Configuration 20)

The transfer mask according to Configuration 19, in which the light shielding film includes a material containing chromium.

### (Configuration 21)

A method of manufacturing a semiconductor device including the step of using the transfer mask according to any of Configurations 11 to 20 and exposure-transferring a pattern on a transfer mask to a resist film on a semiconductor substrate. [Effect of the Disclosure]

The mask blank of this disclosure has a structure where an etching stopper film and a thin film for pattern formation are stacked in this order on a transparent substrate, featured in that the thin film includes a material containing silicon, the etching stopper film includes a material containing hafnium, aluminum, and oxygen, and a ratio by atom % of an amount of the hafnium to a total amount of hafnium and aluminum in the etching stopper film is 0.86 or less. With the mask blank having such a structure, the etching stopper film can simultaneously achieve the functions of high durability to dry etching with fluorine-based gas used in patterning a thin film for pattern formation and a high transmittance to an exposure light.

### BRIEF DESCRIPTION OF THE DRAWINGS

FIG. 1 is a cross-sectional view showing a configuration of the mask blank of the first embodiment of this disclosure.

FIG. 2 is a cross-sectional view showing a configuration of the transfer mask (phase shift mask) of the first embodiment of this disclosure.

FIGS. 3A-3F are schematic cross-sectional views showing the manufacturing step of the transfer mask of the first embodiment of this disclosure.

FIG. 4 is a cross-sectional view showing a configuration of the mask blank of the second embodiment of this disclosure.

FIG. 5 is a cross-sectional view showing a configuration of the transfer mask (binary mask) of the second embodiment of this disclosure.

FIGS. 6A-6D are schematic cross-sectional views showing the manufacturing step of the transfer mask of the second embodiment of this disclosure.

FIG. 7 is a cross-sectional view showing a configuration of the transfer mask (CPL mask) of the third embodiment of this disclosure.

FIG. 8 is a schematic cross-sectional view showing the manufacturing step of the transfer mask of the third embodiment of this disclosure.

FIGS. 9A-9G are schematic cross-sectional views showing the manufacturing step of the phase shift mask of the third embodiment of this disclosure.

FIG. 10 is a graph showing a relationship between a mixture ratio of hafnium and aluminum in the etching stopper film and its transmittance to an ArF exposure light (ArF transmittance).

### EMBODIMENTS FOR CARRYING OUT THE DISCLOSURE

First, the proceeding that has resulted in the completion of this disclosure is described. The inventors of this application diligently studied to solve the technical problem of an etching stopper film including a mixture of hafnium oxide and aluminum oxide. As a result, the inventors found that a ratio of hafnium (Hf) content [atom %] to a total content [atom %] of hafnium (Hf) and aluminum (Al) in a material forming an etching stopper film (Hf/[Hf+Al] ratio) of 0.86 or less can increase a transmittance to an ArF exposure light and can enhance durability to dry etching with fluorine-based gas compared to an etching stopper film including hafnium oxide.

The result of the diligent study is that, to solve the technical problem of the etching stopper film including a mixture of hafnium oxide and aluminum oxide, the mask blank of this disclosure has a structure where an etching stopper film and a thin film for pattern formation are stacked in this order on a transparent substrate, featured in that the thin film includes a material containing silicon, the etching stopper film includes a material containing hafnium, aluminum, and oxygen, and a ratio by atom % of an amount of the hafnium to a total amount of the hafnium and the aluminum in the etching stopper film is 0.86 or less. Next, each embodiment of this disclosure is explained.

### First Embodiment

### [Mask Blank and its Manufacture]

A mask blank according to a first embodiment of this disclosure includes a phase shift film as a thin film for pattern formation which, provides a phase difference with a predetermined transmittance to an exposure light, which is used for manufacturing a phase shift mask (transfer mask). FIG. 1 shows a configuration of the mask blank of the first embodiment. A mask blank 100 according to the first embodiment has an etching stopper film 2, a phase shift film 3 (thin film for pattern formation), a light shielding film 4, and a hard mask film 5 on a main surface of a transparent substrate 1.

There is no particular limitation to the transparent substrate 1, as long as the transparent substrate 1 has a high transmittance to an exposure light. In this disclosure, a synthetic quartz glass substrate and other types of glass substrates (e.g., soda-lime glass, aluminosilicate glass, etc.) can be used. Among these substrates, a synthetic quartz glass substrate is particularly preferable for the mask blank substrate of this disclosure used in forming a high-fineness transfer pattern for having a high transmittance to an ArF excimer laser or at a region with shorter wavelength. However, all of these glass substrates are likely to be etched by dry etching with fluorine-based gas. Therefore, there is a significant meaning to provide the etching stopper film 2 on the transparent substrate 1.

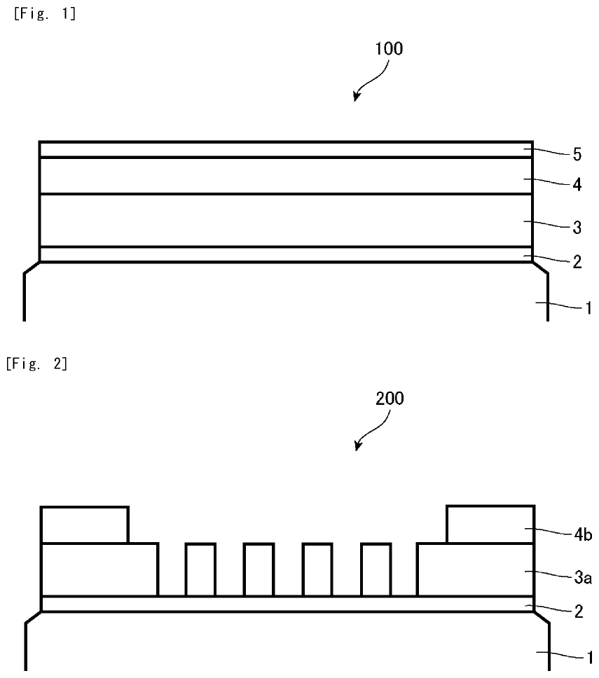

The etching stopper film 2 is formed of a material containing hafnium, aluminum, and oxygen. The etching stopper film 2 is left without being removed on the entire surface of at least a transfer pattern forming region at the stage of completion of a phase shift mask 200 (see FIG. 2). Namely, the etching stopper film 2 remains also in a transmitting portion, which is a region in the phase shift pattern without the phase shift film 3. Therefore, the etching stopper film 2 is preferably formed in contact with a main surface of the transparent substrate 1 without any intervening film between the transparent substrate 1.

The etching stopper film 2 preferably has a ratio by atom % of an amount of hafnium to a total amount of the hafnium and aluminum (may hereafter be referred to as Hf/[Hf+Al] ratio) of 0.86 or less. This point is explained together with FIG. 10. FIG. 10 is a graph showing a relationship between a mixture ratio of hafnium and aluminum in the etching stopper film and its transmittance to an ArF exposure light (Arf transmittance; provided that transmittance of the transparent substrate 1 to ArF exposure light is 100%). As shown in FIG. 10, the inventors measured a transmittance to an ArF exposure light of etching stopper films with varying mixture ratios of hafnium and aluminum, formed on a plurality of substrates with film thickness of 2 nm or 3 nm. As a result, a ratio by atom % of an amount of hafnium to a total amount of hafnium and aluminum of 0.86 or less showed a high transmittance in the etching stopper film of any film thickness than an etching stopper film formed only of hafnium oxide (ratio 1.0 in FIG. 10). Dry etching durability to fluorine-based gas was enhanced in any film thickness compared to an etching stopper film formed only of hafnium oxide.

Hf/[Hf+Al] ratio of the etching stopper film 2 is preferably 0.80 or less. Hf/[Hf+Al] ratio of the etching stopper film 2 is more preferably 0.75 or less. In this case, a transmittance to an ArF exposure light can be 90% or more even with 3 nm film thickness of the etching stopper film 2.

On the other hand, on the viewpoint of resistance to chemical cleaning (esp., alkali cleaning such as ammonium hydrogen peroxide mixture and TMAH), the etching stopper film 2 preferably has Hf/[Hf+Al] ratio of 0.40 or more. Further, on the viewpoint of chemical cleaning using a mixed solution of ammonia water, hydrogen peroxide, and deionized water referred to as SC-1 cleaning, the etching stopper film 2 preferably has Hf/[Hf+Al] ratio of 0.60 or more.

The etching stopper film 2 preferably contains metals other than aluminum and hafnium of 2 atom % or less, more preferably 1 atom % or less, and even more preferably detection lower limit or less through composition analysis of X-ray photoelectron spectroscopy. This is because the etching stopper film 2 containing metals other than aluminum and hafnium causes reduction in a transmittance to an exposure light. Further, a total content of elements other than aluminum, hafnium, and oxygen of the etching stopper film 2 is preferably 5 atom % or less, and more preferably 3 atom % or less. In other words, a total content of aluminum, hafnium, and oxygen of the etching stopper film 2 is preferably 95 atom % or more, and more preferably 97 atom % or more.

The etching stopper film 2 is preferably made of a material including hafnium, aluminum, and oxygen. The material including hafnium, aluminum, and oxygen indicates a material containing, in addition to these constituent elements, only the elements inevitably contained in the etching stopper film 2 when the film is formed by a sputtering method (noble gas such as helium (He), neon (Ne), argon (Ar), krypton (Kr), and xenon (Xe), hydrogen (H), carbon (C), etc.). By minimizing the presence of other elements that bond to hafnium and aluminum in the etching stopper film 2, a ratio of bonding of hafnium and oxygen, and bonding of aluminum and oxygen in the etching stopper film 2 can be significantly increased. Accordingly, etching durability to dry etching with fluorine-based gas can be further enhanced, resistance to chemical cleaning can be further enhanced, and a transmittance to an exposure light can be further enhanced. The etching stopper film preferably has an amorphous structure. More concretely, the etching stopper film 2 preferably has an amorphous structure in a state including a bond of hafnium and oxygen and a bond of aluminum and oxygen. Thus, a surface roughness of the etching stopper film 2 can be improved, and a transmittance to an exposure light can also be enhanced.

While the etching stopper film 2 preferably has a higher transmittance to an exposure light, since the etching stopper film is simultaneously required to have sufficient etching selectivity to fluorine-based gas between the transparent substrate 1, it is difficult to apply a transmittance to an exposure light that is similar to a transmittance of the transparent substrate 1 (i.e., when a transmittance of the transparent substrate 1 (synthetic quarts glass) to an exposure light is 100%, a transmittance of the etching stopper film 2 is less than 100%). A transmittance of the etching stopper film 2 when a transmittance of the transparent substrate 1 to an exposure light is 100% is preferably 85% or more, and more preferably 90% or more.

An oxygen content of the etching stopper film 2 is preferably 60 atom % or more, more preferably 61.5 atom % or more, and even more preferably 62 atom % or more. This is because the etching stopper film 2 requires a large amount of oxygen in order to make a transmittance to an exposure light equal to or greater than the aforementioned value. On the other hand, the oxygen content of the etching stopper film 2 is preferably 66 atom % or less.

The thickness of the etching stopper film 2 is preferably 2 nm or more. Considering the influence of dry etching with fluorine-based gas and the influence of chemical cleaning performed during manufacture of the transfer mask from the mask blank, the thickness of the etching stopper film 2 is more preferably 3 nm or more.

Although the etching stopper film 2 is made of a material having a high transmittance to an exposure light, a transmittance decreases as the thickness increases. Further, the etching stopper film 2 has a higher refractive index than the material forming the transparent substrate 1, and as the thickness of the etching stopper film 2 increases, the influence on designing a mask pattern (pattern with bias correction, OPC, SRAF, etc.) to be actually formed in the phase shift film 3 increases. Considering these points, the etching stopper film 2 is preferably 10 nm or less, more preferably 8 nm or less, and even more preferably 6 nm or less.

A refractive index n to an exposure light of an ArF excimer laser (hereafter simply referred to as refractive index n) of the etching stopper film 2 is preferably 2.90 or less, and more preferably 2.86 or less. This is to reduce the influence in designing a mask pattern to be actually formed in the phase shift film 3. Further, since the etching stopper film 2 is formed of a material containing hafnium and aluminum, a refractive index n of the etching stopper film 2 cannot be the same as the transparent substrate 1. A refractive index n of the etching stopper film 2 is preferably 2.10 or more, and more preferably 2.20 or more. On the other hand, an extinction coefficient k to an exposure light of an ArF excimer laser (hereafter simply referred to as extinction coefficient k) of the etching stopper film 2 is preferably 0.30 or less, and more preferably 0.29 or less. This is to enhance a transmittance of the etching stopper film 2 to an exposure light. An extinction coefficient k of the etching stopper film 2 is preferably 0.06 or more.

The etching stopper film 2 preferably has a high uniformity of composition in the thickness direction (difference in content amount of each constituent element in the thickness direction is within a variation width of 5 atom %). On the other hand, the etching stopper film 2 can be formed as a film structure with a composition gradient in the thickness direction. In this case, it is preferable to apply a composition gradient where Hf/[Hf+Al] ratio of the etching stopper film 2 at the transparent substrate 1 side is lower than Hf/[Hf+Al] ratio at the phase shift film 3 side. This is because while the etching stopper film 2 is preferentially desired to have higher chemical resistance at the phase shift film 3 side, a higher transmittance to an exposure light is desired at the transparent substrate 1 side.

An additional film can be intervened between the transparent substrate 1 and the etching stopper film 2. In this case, the additional film is desired to include a material with a higher transmittance to an exposure light and a less refractive index n than the etching stopper film 2. When a phase shift mask is manufactured from a mask blank, a stacked structure of the additional film and the etching stopper film 2 exists at a transmitting portion of the phase shift mask without a pattern of the phase shift film 3. This is because the transmitting portion is desired to have a high transmittance to an exposure light, and it is necessary to increase a transmittance to an exposure light of the entire stacked structure. The material of the additional film includes, for example, a material including silicon and oxygen, or a material having added thereto one or more elements selected from hafnium, zirconium, titanium, vanadium, and boron. The additional film can be formed of a material containing hafnium, aluminum, and oxygen, with Hf/[Hf+Al] ratio lower than the etching stopper film 2.

The phase shift film 3 includes a material containing silicon.

The phase shift film 3 preferably has a function to transmit an exposure light at a transmittance of 1% or more (transmittance) and a function to generate a phase difference of 150 degrees or more and 210 degrees or less between an exposure light transmitted through the phase shift film 3 and the exposure light transmitted through the air by the same distance as the thickness of the phase shift film 3. A transmittance of the phase shift film 3 is more preferably 2% or more. A transmittance of the phase shift film 3 is more preferably 30% or less, and even more preferably 20% or less.

The thickness of the phase shift film 3 is preferably 80 nm or less, and more preferably 70 nm or less. Further, to reduce variation width of the best focus by pattern line width of the phase shift pattern, the thickness of the phase shift film 3 is particularly preferably 65 nm or less. The thickness of the phase shift film 3 is preferably 50 nm or more. This is because 50 nm or more thickness is required to form the phase shift film 3 with an amorphous material while achieving a phase difference of the phase shift film 3 of 150 degrees or more.

For the phase shift film 3 to satisfy the conditions regarding the optical properties and film thickness mentioned above, a refractive index n of the phase shift film to an exposure light (ArF exposure light) is preferably 1.9 or more, and more preferably 2.0 or more. Further, a refractive index n of the phase shift film 3 is preferably 3.1 or less, and more preferably 2.7 or less. An extinction coefficient k of the phase shift film 3 to an ArF exposure light is preferably 0.26 or more, and more preferably 0.29 or more. Further, an extinction coefficient k of the phase shift film 3 is preferably 0.62 or less, and more preferably 0.54 or less.

On the other hand, there may be a case where the phase shift film 3 has a stacked structure including one or more sets of a low transmitting layer formed of a material with a relatively low transmittance to an exposure light and a high transmitting layer formed of a material with a relatively high transmittance to an exposure light. In this case, the low transmitting layer is preferably formed of a material where a refractive index n to an ArF exposure light is less than 2.5 (preferably 2.4 or less, more preferably 2.2 or less, even more preferably 2.0 or less) and an extinction coefficient k is 1.0 or more (preferably 1.1 or more, more preferably 1.4 or more, even more preferably 1.6 or more). Further, the high transmitting layer is preferably made of a material where a refractive index n to an ArF exposure light is 2.5 or more (preferably 2.6 or more) and an extinction coefficient k is less than 1.0 (preferably 0.9 or less, more preferably 0.7 or less, even more preferably 0.4 or less).

Incidentally, a refractive index n and an extinction coefficient k of a thin film including the phase shift film 3 are not determined only by the composition of the thin film. Film density and crystal condition of the thin film are also the factors that affect a refractive index n and an extinction coefficient k. Therefore, the conditions in forming a thin film by reactive sputtering are adjusted so that the thin film reaches a desired refractive index n and extinction coefficient k. For allowing the phase shift film 3 to have a refractive index n and an extinction coefficient k of the above range, not only a ratio of mixed gas of noble gas and reactive gas (oxygen gas, nitrogen gas, etc.) is adjusted in forming a film by reactive sputtering, but various other adjustments are made upon forming a film by reactive sputtering, such as pressure in a film forming chamber, power applied to the sputtering target, and positional relationship such as the distance between the target and the transparent substrate 1. Further, these film forming conditions are unique to film forming apparatuses which are adjusted arbitrarily so that the phase shift film 3 to be formed reaches the desired refractive index n and extinction coefficient k.

Generally, the phase shift film 3 including a material containing silicon is patterned through dry etching with fluorine-based gas. The transparent substrate 1 including a glass material is likely to be etched by dry etching with fluorine-based gas, and has low durability particularly to fluorine-based gas containing carbon. Therefore, dry etching with fluorine-based gas free of carbon (SF₆, etc.) as etching gas is often applied in patterning the phase shift film 3. However, in patterning the phase shift film 3 by dry etching with fluorine-based gas using an etching mask pattern such as a resist pattern as a mask, the dry etching being stopped at the stage of initially reaching a lower edge of the phase shift film 3 (referred to as just etching; time required from initiation of etching to the stage of just etching is called just etching time) causes low verticality of a sidewall of the phase shift pattern, which affects exposure transfer performance as a phase shift mask. The pattern to be formed in the phase shift film 3 has in-plane sparse/dense difference in the mask blank, and advancement of dry etching is slow in a portion with rather dense pattern.

Due to these circumstances, upon dry etching of the phase shift film 3, additional etching is further continued (over etching) after reaching the just etching stage to enhance verticality of the sidewall of the phase shift pattern, and to enhance in-plane CD uniformity of the phase shift pattern (time between the end of just etching to the end of over etching is called over etching time). In the case where the etching stopper film 2 does not exist between the transparent substrate 1 and the phase shift film 3, since over etching the phase shift film 3 causes advancement of etching in the pattern sidewall of the phase shift film 3 and at the same time advancement of etching in the surface of the transparent substrate 1, a prolonged time of over etching cannot be made (etching was stopped around 4 nm from transparent substrate surface) so that there was a limitation to enhance verticality of the phase shift pattern.

For the purpose of further enhancing verticality of the sidewall of the phase shift pattern, application of higher bias voltage than conventional cases upon dry etching of the phase shift film 3 (hereafter “high bias etching”) is conducted. A problem in the high bias etching is the occurrence of so-called micro trench, a phenomenon where the transparent substrate 1 in vicinity of the sidewall of the phase shift pattern is locally dug by etching. The occurrence of the micro trench is considered to be caused by a charge-up generated by applying bias voltage on the transparent substrate 1 causing ionized etching gas to go around to the sidewall of the phase shift pattern having a resistance value lower than the transparent substrate 1.

Since the etching stopper film 2 of the first embodiment is formed of a material containing hafnium, aluminum, and oxygen, and has Hf/[Hf+Al] ratio of 0.86 or less, over etching the phase shift film 3 does not cause elimination of the etching stopper film 2 and the micro trench that is likely to occur by high bias etching can be prevented.

The phase shift film 3 can be formed of a material containing silicon and nitrogen. Including nitrogen in silicon can increase a refractive index n (large phase difference can be obtained with less thickness) and can reduce an extinction coefficient k (can increase transmittance) than a material consisting only of silicon, and optical properties that are preferable as a phase shift film can be obtained.

The phase shift film 3 can be formed of a material including silicon and nitrogen, or a material including silicon, nitrogen, and one or more elements selected from a metalloid element, a non-metallic element, and noble gas (the materials are hereafter generally referred to as “silicon nitride-based material”). The phase shift film 3 of a silicon nitride-based material can contain any metalloid elements. Among these metalloid elements, it is preferable to include one or more elements selected from boron, germanium, antimony, and tellurium, since enhancement in conductivity of silicon to be used as a sputtering target in forming the phase shift film 3 by sputtering can be expected.

The phase shift film 3 of silicon nitride-based material can include noble gas such as helium (He), neon (Ne), argon (Ar), krypton (Kr), and xenon (Xe). The phase shift film 3 of a silicon nitride-based material can contain oxygen. The phase shift film 3 of a silicon nitride-based material containing oxygen can achieve both of the function of having 20% or more transmittance to an exposure light of an ArF excimer laser and the function of having a phase difference of the above range.

The phase shift film 3 of a silicon nitride-based material can be configured from a single layer except for the surface layer where oxidization is inevitable (oxidized layer), or a stack of multiple layers. In the case of the phase shift film 3 of a stacked structure of multiple layers, the stacked structure can be a combination of a layer of a silicon nitride-based material (SiN, SiON, etc.) with a layer of a silicon oxide-based material (SiO₂, etc.).

While the phase shift film 3 of a silicon nitride-based material is formed by sputtering, any sputtering method is applicable such as DC sputtering, RF sputtering, and ion beam sputtering. In the case of using a target with low conductivity (silicon target, silicon compound target free of or including a small amount of metalloid element, etc.), while application of RF sputtering and ion beam sputtering is preferable, application of RF sputtering is more preferable considering the deposition rate.

Etching end point detection of EB defect repair is performed by detecting at least one of Auger electron, secondary electron, characteristic X-ray, and backscattered electron, which are discharged from an irradiated portion when an electron beam is irradiated on a black defect. For example, in the case of detecting Auger electrons discharged from the portion irradiated with an electron beam, change of material composition is mainly observed by Auger electron spectroscopy (AES). In the case of detecting secondary electrons, change of surface shape is mainly observed from SEM image. Further, in the case of detecting characteristic X-ray, change of material composition is mainly observed by energy dispersive X-ray spectrometry (EDX) or wavelength-dispersive X-ray spectrometry (WDX). In the case of detecting backscattered electrons, change of material composition and crystal state is mainly observed by electron beam backscatter diffraction (EBSD).

In a mask blank with a configuration where the phase shift film (both single layer film and multilayer film) 3 of a silicon-based material is provided in contact with a main surface of the transparent substrate 1 of a glass material, while the majority of components in the phase shift film 3 are silicon, nitrogen, and oxygen, a majority of components in the transparent substrate 1 is silicon and oxygen, with slight difference therebetween. Therefore, in this combination, etching correction of EB defect repair was hard to detect. On the other hand, in a configuration where the phase shift film 3 is provided in contact with a surface of the etching stopper film 2, while the majority of the components of the phase shift film 3 are silicon and nitrogen, the etching stopper film 2 contains hafnium, aluminum, and oxygen. Therefore, etching repair of EB defect repair can be based on the detection of aluminum or hafnium, resulting in rather easier detection of an end point.

On the other hand, the phase shift film 3 can be formed of a material containing a transition metal, silicon, and nitrogen. The transition metal in this case includes one or more metals among molybdenum (Mo), tantalum (Ta), tungsten (W), titanium (Ti), chromium (Cr), nickel (Ni), vanadium (V), zirconium (Zr), ruthenium (Ru), rhodium (Rh), zinc (Zn), niobium (Nb), palladium (Pd), etc., or an alloy of these metals. The material of the phase shift film 3 can contain, in addition to the aforementioned elements, elements such as nitrogen (N), oxygen (O), carbon (C), hydrogen (H), boron (B), etc. The material of the phase shift film 3 can include inert gas such as helium (He), argon (Ar), krypton (Kr), and xenon (Xe). Considering detection of etching end point of EB defect repair, it is preferable not to include aluminum and hafnium in the phase shift film 3.

The phase shift film 3 is required to have a ratio calculated by dividing a transition metal (M) content [atom %] by a total content [atom %] of transition metal (M) and silicon (Si) (hereafter M/[M+Si] ratio) in the film of 0.15 or less. As a transition metal content in the phase shift film 3 increases, the etching rate of dry etching with fluorine-based gas free of carbon (SF₆, etc.) increases and can easily obtain etching selectivity between the transparent substrate 1; however, it is still insufficient. Further, the M/[M+Si] ratio of the phase shift film 3 being higher than the above, necessitates an increase in oxygen content to obtain a desired transmittance, which may cause increased thickness of the phase shift film 3, and is not preferable.

On the other hand, the M/[M+Si] ratio of the phase shift film 3 is preferably 0.01 or more. This is because in manufacturing the phase shift mask 200 from the mask blank 100, it is preferable that sheet resistance of the phase shift film 3 is low when applying defect repair by electron beam radiation and non-excitation gas such as XeF₂ on a black defect existing in the pattern of the phase shift film 3.

On the other hand, by providing the etching stopper film 2 in contact with a main surface of the transparent substrate 1, further providing the phase shift film 3 in contact with an upper surface of the etching stopper film 2, and further adjusting conditions of the etching stopper film 2 and the phase shift film 3, a back surface reflectance to an ArF exposure light (reflectance to an ArF exposure light entered from the transparent substrate 1 side) can be increased (e.g., 20% or more). For example, the conditions can be adjusted as follows. The etching stopper film 2 has a refractive index n to an ArF exposure light of 2.3 or more and 2.9 or less, an extinction coefficient k of 0.06 or more and 0.30 or less, and a film thickness of 2 nm or more and 6 nm or less. The phase shift film 3 has, in its entirety in the case of a single layer structure and a layer contacting the etching stopper film 2 in the case of a structure with two or more layers, a refractive index n to an ArF exposure light of 2.0 or more and 3.1 or less, an extinction coefficient k of 0.26 or more and 0.54 or less, and a film thickness of 50 nm or more. Further, the etching stopper film 2 can have an Hf/[Hf+Al] ratio of 0.50 or more and 0.86 or less, an oxygen content of 61.5 atom %, and a film thickness of 2 nm or more and 6 nm or less.

The mask blank 100 having the above configuration has a back surface reflectance to an ArF exposure light that is higher than conventional cases. The phase shift mask 200 manufactured from the mask blank 100 can reduce temperature rise caused by heat of the phase shift film 3 that generates when the phase shift mask 200 is set on an exposure apparatus and an ArF exposure light is irradiated from the transparent substrate 1 side. Accordingly, a phenomenon can be prevented where the etching stopper film 2 and the transparent substrate 1 thermally expand by heat of the phase shift film 3 being conducted to the etching stopper film 2 and the transparent substrate 1 and the pattern of the phase shift film 3 is displaced. Further, durability of the phase shift film 3 to irradiation of an ArF exposure light (ArF light fastness) can be enhanced.

A single layer structure and a stacked structure of two or more layers are applicable to the light shielding film 4. Further, each layer in the light shielding film of a single layer structure and the light shielding film of a stacked structure of two or more layers can be configured by approximately the same composition in the thickness direction of the layer or the film, or with a composition gradient in the thickness direction of the layer.

The mask blank 100 in FIG. 1 has a configuration where the light shielding film 4 is stacked on the phase shift film 3 without an intervening film. For the light shielding film 4 of this configuration, it is necessary to apply a material having a sufficient etching selectivity to etching gas used in forming a pattern in the phase shift film 3.

The light shielding film 4 in this case is preferably formed of a material containing chromium. Materials containing chromium for forming the light shielding film 4 can include, in addition to chromium metal, a material containing chromium (Cr) and one or more elements selected from oxygen (O), nitrogen (N), carbon (C), boron (B), and fluorine (F).

Incidentally, the mask blank of this disclosure is not limited to those shown in FIG. 1, but can be configured to have an additional film (etching mask and stopper film) intervening between the phase shift film 3 and the light shielding film 4. In this case, a preferable configuration is that the etching mask and stopper film is formed of the material containing chromium given above, and the light shielding film 4 is formed of a material containing silicon.

A material containing silicon for forming the light shielding film 4 can include a transition metal, and can include metal elements other than the transition metal. The reason is that the pattern formed in the light shielding film 4 is basically a light shielding band pattern of an outer peripheral region having less accumulation of irradiation of an ArF exposure light compared to a transfer pattern region, and a fine pattern is rarely arranged in the outer peripheral region, so that substantial problems hardly occur even if ArF light fastness is low. Another reason is that including a transition metal in the light shielding film 4 significantly enhances light shielding performance compared to the case without a transition metal, which enables reduction of the thickness of the light shielding film 4. The transition metals to be included in the light shielding film 4 include any one of metals such as molybdenum (Mo), tantalum (Ta), tungsten (W), titanium (Ti), chromium (Cr), hafnium (Hf), nickel (Ni), vanadium (V), zirconium (Zr), ruthenium (Ru), rhodium (Rh), niobium (Nb), and palladium (Pd), or a metal alloy thereof.

The light shielding film 4 forms a light shielding band, etc. in the stacked structure with the phase shift film 3 after completion of the phase shift mask 200. Therefore, the light shielding film 4 is desired to ensure an optical density (OD) greater than 2.0, preferably 2.8 nm or more OD, and more preferably 3.0 or more OD in the stacked structure with the phase shift film 3.

In this embodiment, the hard mask film 5 stacked on the light shielding film 4 is formed of a material having etching selectivity to etching gas used in etching the light shielding film 4. Accordingly, a thickness of the resist film can be significantly reduced compared to the case of using the resist film directly as a mask of the light shielding film 4 as will be mentioned below.

Since the light shielding film 4 must ensure a predetermined optical density and have a sufficient light shielding function, there is a limitation to reduce its thickness. On the other hand, it is sufficient for the hard mask film 5 to have a film thickness that can function as an etching mask until completion of dry etching for forming a pattern in the light shielding film 4 immediately below, and basically is not optically limited. Therefore, the thickness of the hard mask film 5 can be reduced significantly compared to the thickness of the light shielding film 4. Since a resist film of an organic material only requires a film thickness to function as an etching mask until dry etching for forming a pattern in the hard mask film 5 is completed, the thickness of the resist film can be reduced significantly compared to the case of using the resist film directly as a mask of the light shielding film 4. Since the thickness of the resist film can be reduced as mentioned above, resist resolution can be enhanced and collapse of the pattern to be formed can be prevented.

While it is preferable to form the hard mask film 5 stacked on the light shielding film 4 from the above materials, this disclosure is not limited to this embodiment, and the mask blank 100 can include a resist pattern directly formed on the light shielding film 4 without forming the hard mask film 5, and the light shielding film 4 can be etched directly with the resist pattern as a mask.

In the case where the light shielding film 4 is formed of a material containing chromium, the hard mask film 5 is preferably formed of the material containing silicon given above. Since the hard mask film 5 in this case tends to have low adhesiveness with the resist film of an organic material, it is preferable to treat the surface of the hard mask film 5 with HMDS (Hexamethyldisilazane) to enhance surface adhesiveness. The hard mask film 5 in this case is more preferably made of SiO₂, SiN, SiON, etc.

Further, in the case where the light shielding film 4 is formed of a material containing chromium, materials containing tantalum are also applicable as the materials of the hard mask film 5. The material containing tantalum in this case includes, in addition to tantalum metal, a material containing tantalum and one or more elements selected from nitrogen, oxygen, boron, and carbon.

In the mask blank 100, a resist film of an organic material is preferably formed in contact with a surface of the hard mask film 5 at a film thickness of 100 nm or less.

While the etching stopper film 2, the phase shift film 3, the light shielding film 4, and the hard mask film 5 are formed by sputtering, any sputtering method is applicable such as DC sputtering, RF sputtering, and ion beam sputtering. In the case where the target has low conductivity, while application of RF sputtering and ion beam sputtering is preferable, application of RF sputtering is more preferable considering the deposition rate.

In the method of forming the etching stopper film 2, it is preferable to arrange two targets, i.e., a mixed target of hafnium and oxygen and a mixed target of aluminum and oxygen in a film forming chamber to form the etching stopper film 2 on the transparent substrate 1. Concretely, the transparent substrate 1 is placed on a substrate stage in the film forming chamber, and a predetermined voltage is applied (preferably RF power source in this case) to each of the two targets under a noble gas atmosphere such as argon gas (or mixed gas atmosphere with oxygen gas or oxygen-containing gas). As a result, plasmarized noble gas particles collide with the two targets, each causing a sputtering phenomenon, and the etching stopper film 2 containing hafnium, aluminum, and oxygen is formed on the surface of the transparent substrate 1. In this case, it is more preferable to apply HfO₂ target and Al₂O₃ target as the two targets.

In addition to the above, the etching stopper film 2 can be formed only of a mixed target of hafnium, aluminum, and oxygen (preferably a mixed target of HfO₂ and Al₂O₃; same hereafter). Further, the etching stopper film 2 can be formed by simultaneously discharging a mixed target of hafnium, aluminum, and oxygen and a hafnium target, or a mixed target of hafnium and oxygen and an aluminum target. Moreover, the etching stopper film 2 can be formed by simultaneously discharging two targets, i.e., a hafnium target and an aluminum target, under a mixed gas atmosphere of noble gas and oxygen gas or oxygen-containing gas.

As mentioned above, the mask blank 100 of the first embodiment includes an etching stopper film 2 containing hafnium, aluminum, and oxygen between the transparent substrate 1 and the phase shift film 3 which is a thin film for pattern formation, and a ratio by atom % of the hafnium content to a total content of hafnium and aluminum in the etching stopper film 2 is 0.86 or less. The etching stopper film 2 simultaneously satisfies the properties of having higher durability to dry etching with fluorine-based gas performed in forming a pattern in the phase shift film 3 and having higher transmittance to an exposure light compared to an etching stopper film formed of hafnium oxide. Accordingly, since over etching can be made without digging a main surface of the transparent substrate 1 in forming a transfer pattern in the phase shift film 3 by dry etching with fluorine-based gas, verticality of the pattern sidewall can be enhanced, and in-plane CD uniformity of the pattern can be enhanced.

On the other hand, when the transfer mask (phase shift mask) 200 was manufactured from the mask blank 100 of the first embodiment, since the etching stopper film 2 has a higher transmittance to an exposure light than conventional etching stopper films, a transmittance of a transmitting portion where the phase shift film 3 is removed is enhanced. Accordingly, a phase shift effect is enhanced between an exposure light that transmitted through the pattern of the phase shift film 3 and the etching stopper film 2, and an exposure light that transmitted through only the etching stopper film 2. Therefore, a high pattern resolution can be obtained when the transfer mask is used to exposure-transfer a resist film on a semiconductor substrate.

### [Transfer Mask (Phase Shift Mask) and its Manufacture]

The transfer mask (phase shift mask) 200 (see FIG. 2) of the first embodiment is featured in that the etching stopper film 2 of the mask blank 100 is left on the entire main surface of the transparent substrate 1, a transfer pattern (phase shift pattern 3a) is formed in the phase shift film 3, and a pattern including a light shielding band (light shielding pattern 4b: light shielding band, light shielding patch, etc.) is formed in the light shielding film 4. In the case of a configuration where a hard mask film 5 is provided on the mask blank 100, the hard mask film 5 is removed during manufacture of the phase shift mask 200.

The transfer mask (phase shift mask) 200 of the first embodiment is featured in having a structure where an etching stopper film 2 and a phase shift pattern 3a which is a phase shift film having a transfer pattern, are stacked in this order on a main surface of the transparent substrate 1, the phase shift pattern 3a is formed of a material containing silicon, the etching stopper film 2 is formed of a material containing hafnium, aluminum, and oxygen, and a ratio by atom % of hafnium content to a total amount of hafnium and aluminum is 0.86 or less. Further, the phase shift mask 200 has a light shielding pattern 4b which is a light shielding film having a pattern including a light shielding band on the phase shift pattern 3a.

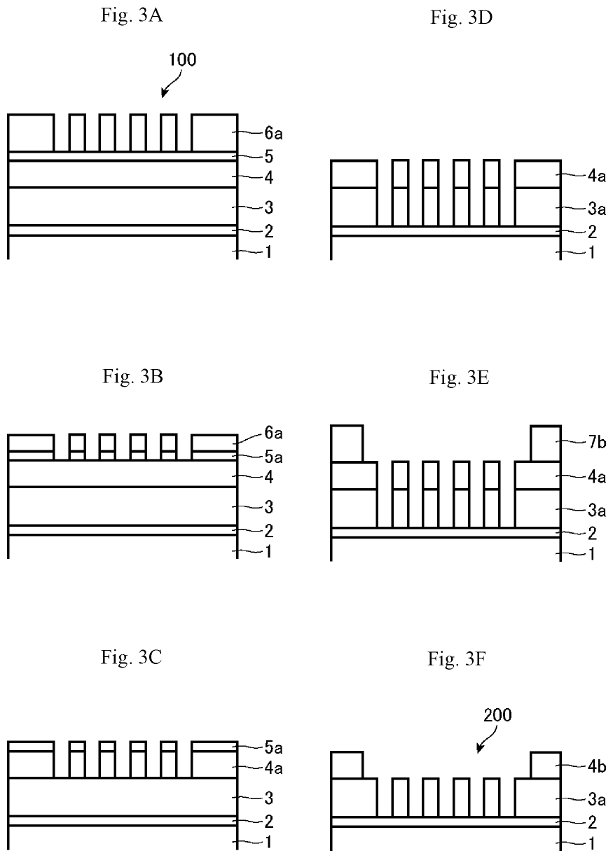

The method of manufacturing the phase shift mask of the first embodiment uses the mask blank 100 mentioned above, which is featured in including the steps of forming a transfer pattern in the light shielding film 4 by dry etching; forming a transfer pattern in the phase shift film 3 by dry etching using fluorine-based gas with the light shielding film 4 having the transfer pattern as a mask; and forming a pattern including a light shielding band (light shielding band, light shielding patch, etc.) in the light shielding film 4 by dry etching. The method of manufacturing the phase shift mask 200 of the first embodiment is explained below according to the manufacturing steps shown in FIGS. 3A-3F. Explained herein is the method of manufacturing the phase shift mask 200 using the mask blank 100 having the hard mask film stacked on the light shielding film 4. Further, a material containing chromium is applied to the light shielding film 4, and a material containing silicon is applied to the hard mask film 5 in this case.

First, a resist film is formed in contact with the hard mask film 5 of the mask blank 100 by spin coating. Next, a first pattern, which is a transfer pattern (phase shift pattern) to be formed in the phase shift film 3, was written with an electron beam in the resist film, and a predetermined treatment such as developing was conducted, to thereby form a first resist pattern 6a having a phase shift pattern (see FIG. 3A). Subsequently, dry etching using fluorine-based gas is conducted with the first resist pattern 6a as a mask, and a first pattern (hard mask pattern 5a) is formed in the hard mask film 5 (see FIG. 3B).

Next, after removing the resist pattern 6a, dry etching is conducted using mixed gas of chlorine-based gas and oxygen gas with the hard mask pattern 5a as a mask, and a first pattern (light shielding pattern 4a) is formed in the light shielding film 4 (see FIG. 3C). Subsequently, dry etching is conducted using fluorine-based gas with the light shielding pattern 4a as a mask, and a first pattern (phase shift pattern 3a) is formed in the phase shift film 3, and at the same time the hard mask pattern 5a is removed (see FIG. 3D).

In dry etching of the phase shift film 3 with fluorine-based gas, an additional etching (over etching) is done to enhance verticality of the sidewall of the pattern of the phase shift pattern 3a and to enhance in-plane CD uniformity of the phase shift pattern 3a. Even after the over etching, a surface of the etching stopper film 2 is only slightly etched and a surface of the transparent substrate 1 is not exposed at the transmitting portion of the phase shift pattern 3a.

Next, a resist film is formed on the mask blank 100 by spin coating. Thereafter, a second pattern, which is a pattern (light shielding pattern) to be formed in the light shielding film 4, was written with an electron beam in the resist film, and a predetermined treatment such as developing was conducted, to thereby form a second resist pattern 7b having a light shielding pattern (see FIG. 3E). Since the second pattern is rather large, it is possible to employ an exposure writing by a laser light using a laser writing apparatus having high throughput, in place of an electron beam writing.

Subsequently, dry etching is conducted using mixed gas of chlorine-based gas and oxygen gas with the second resist pattern 7b as a mask, and a second pattern (light shielding pattern 4b) is formed in the light shielding film 4. Further, the second resist pattern 7b is removed, predetermined treatments such as cleaning are conducted, and the phase shift mask 200 is obtained (see FIG. 3F). While SC-1 cleaning was used in the cleaning step, variation was observed in the film reduction amount of the etching stopper film 2 depending on Hf/[Hf+Al] ratio as shown in the Examples and Comparative Examples given below.

There is no particular limitation to chlorine-based gas to be used for the dry etching described above, as long as chlorine (Cl) is included. The chlorine-based gas includes, for example, Cl₂, SiCl₂, CHCl₃, CH₂Cl₂, and BCl₃. Further, there is no particular limitation to fluorine-based gas to be used for the dry etching described above as long as fluorine (F) is included, since the mask blank 100 has the etching stopper film 2 on the transparent substrate 1. The fluorine-based gas includes, for example, CHF₃, CF₄, C₂F₆, C₄F₈, and SF₆.

The phase shift mask 200 of the first embodiment is manufactured using the mask blank 100 mentioned above. The etching stopper film 2 simultaneously satisfies the properties of having high durability to dry etching with fluorine-based gas performed in forming a pattern in the phase shift film 3 and having a high transmittance to an exposure light compared to an etching stopper film formed of hafnium oxide. Accordingly, over etching can be done without digging a main surface of the transparent substrate 1 in forming the phase shift pattern (transfer pattern) 3a in the phase shift film 3 by dry etching using fluorine-based gas. Therefore, the phase shift mask 200 of the first embodiment has high verticality of the sidewall of the phase shift pattern 3a and high in-plane CD uniformity of the phase shift pattern 3a.

On the other hand, since the etching stopper film 2 of the phase shift mask 200 of the first embodiment has a higher transmittance to an exposure light than conventional etching stopper films, a transmittance of a transmitting portion where the phase shift film 3 is removed is enhanced. Accordingly, a phase shift effect is enhanced between an exposure light that transmitted through the pattern of the phase shift film 3 and the etching stopper film 2, and an exposure light that transmitted through only the etching stopper film 2. Therefore, a high pattern resolution can be obtained when the phase shift mask 200 is used to exposure-transfer a resist film on a semiconductor substrate.

### [Manufacture of Semiconductor Device]

The method of manufacturing a semiconductor device according to the first embodiment is featured in that a transfer pattern is exposure-transferred to a resist film on a semiconductor substrate using the transfer mask (phase shift mask) 200 of the first embodiment or the transfer mask (phase shift mask) 200 manufactured by using the mask blank 100 of the first embodiment. The phase shift mask 200 of the first embodiment has high verticality of the sidewall of the phase shift pattern 3a and high in-plane CD uniformity of the phase shift pattern 3a. Therefore, when an exposure transfer is made on a resist film on a semiconductor device using the phase shift mask 200 of the first embodiment, a pattern can be formed in the resist film on the semiconductor device at a precision sufficiently satisfying the design specification.

Further, since the etching stopper film 2 of the phase shift mask 200 of the first embodiment has a higher transmittance to an exposure light than conventional etching stopper films, a transmittance of a transmitting portion where the phase shift film 3 is removed is enhanced. Accordingly, a phase shift effect is enhanced between an exposure light that transmitted through the pattern of the phase shift film 3 and the etching stopper film 2, and an exposure light that transmitted through only the etching stopper film 2. Therefore, a high pattern resolution can be obtained when the phase shift mask 200 is used to exposure-transfer a resist film on a semiconductor substrate. In the case where a film to be processed is dry etched to form a circuit pattern using this resist pattern as a mask, a highly precise and high-yield circuit pattern can be formed without short-circuit of wiring and disconnection caused by lack of precision and transfer defect.

### Second Embodiment

### [Mask Blank and its Manufacture]

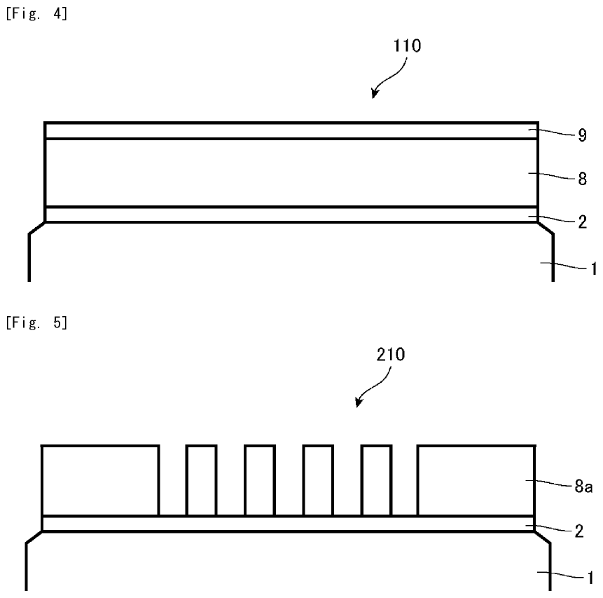

The mask blank according to a second embodiment of this disclosure includes a thin film for pattern formation as a light shielding film having a predetermined optical density, which is used for manufacturing a binary mask (transfer mask). FIG. 4 shows a configuration of a mask blank of the second embodiment. The mask blank 110 of the second embodiment has a structure where an etching stopper film 2, a light shielding film (thin film for pattern formation) 8, and a hard mask film 9 are stacked in order on a transparent substrate 1. Explanation is omitted herein on the configurations that are similar to the mask blank of the first embodiment, using the same reference numerals.

The light shielding film 8 is a thin film for pattern formation into which a transfer pattern is formed when a binary mask 210 is manufactured from the mask blank 110. High light shielding performance is required in a pattern of the light shielding film 8 in a binary mask. OD to an exposure light of 2.8 or more is required by the light shielding film 8 alone, and more preferably, OD of 3.0 or more. A single layer structure and a stacked structure of two or more layers are applicable to the light shielding film 8. Further, each layer in the light shielding film of a single layer structure and the light shielding film with a stacked structure of two or more layers can be configured by approximately the same composition in the thickness direction of the layer or the film, or with a composition gradient in the thickness direction of the layer.

The light shielding film 8 is formed of a material that can pattern a transfer pattern by dry etching with fluorine-based gas. Materials with such a characteristic include a material containing silicon, and a material containing a transition metal and silicon. This is because a material containing a transition metal and silicon has high light shielding performance compared to a material containing silicon and free of a transition metal, which enables reduction of thickness of the light shielding film 8. The transition metals to be included in the light shielding film 8 include any one of metals such as molybdenum (Mo), tantalum (Ta), tungsten (W), titanium (Ti), chromium (Cr), nickel (Ni), vanadium (V), zirconium (Zr), ruthenium (Ru), rhodium (Rh), niobium (Nb), and palladium (Pd), or a metal alloy thereof.

The light shielding film 8 formed of a material containing silicon can contain metals other than a transition metal (tin (Sn), indium (In), gallium (Ga), etc.). However, including aluminum and hafnium in a material containing silicon may cause reduction in etching selectivity to dry etching with fluorine-based gas between the etching stopper film 2, and difficulty in detecting an etching end point when an EB defect repair was performed on the light shielding film 8.

The light shielding film 8 can be formed of a material including silicon and nitrogen, or a material including silicon, nitrogen, and one or more elements selected from a metalloid element, a non-metallic element, and noble gas. The light shielding film 8 in this case can contain any metalloid elements. Among these metalloid elements, it is preferable to include one or more elements selected from boron, germanium, antimony, and tellurium, since enhancement in conductivity of silicon to be used as a target in forming the light shielding film 8 by sputtering can be expected.

In the case where the light shielding film 8 is a stacked structure including a lower layer and an upper layer, the lower layer can be formed of a material including silicon, or a material including silicon and one or more elements selected from carbon, boron, germanium, antimony, and tellurium, and the upper layer can be formed of a material including silicon and nitrogen, or a material including silicon and nitrogen and one or more elements selected from a metalloid element, a non-metallic element, and noble gas.

The material forming the light shielding film 8 can contain one or more elements selected from oxygen, nitrogen, carbon, boron, and hydrogen within the range of not significantly reducing optical density. To reduce reflectance to an exposure light on a surface opposite the transparent substrate 1 of the light shielding film 8, a surface layer opposite the transparent substrate 1 (upper layer in the case of a two layer structure of lower layer and upper layer) can contain a greater amount of oxygen or nitrogen.

The light shielding film 8 can be formed of a material containing tantalum. In this case, silicon content of the light shielding film 8 is preferably 5 atom % or less, and more preferably 3 atom % or less. These materials containing tantalum can pattern a transfer pattern through dry etching with fluorine-based gas. The material containing tantalum in this case includes, in addition to tantalum metal, a material containing tantalum and one or more elements selected from nitrogen, oxygen, boron, and carbon, for example, Ta, TaN, TaO, TaON, TaBN, TaBO, TaBON, TaCN, TaCO, TaCON, TaBCN, and TaBOCN.

The mask blank according to the second embodiment also has a hard mask film 9 on the light shielding film 8. The hard mask film 9 should be formed of a material having etching selectivity to etching gas used in etching the light shielding film 8. Accordingly, a thickness of the resist film can be significantly reduced compared to the case of using the resist film directly as a mask of the light shielding film 8.

The hard mask film 9 is preferably formed of a material containing chromium. The hard mask film 9 is more preferably formed of a material containing chromium and one or more elements selected from nitrogen, oxygen, carbon, hydrogen, and boron. The hard mask film 9 can be formed of a material containing these materials containing chromium, and at least one or more metallic elements selected from indium (In), tin (Sn), and molybdenum (Mo) (these metallic elements are hereinafter referred to as “metallic element including indium, etc.”).

In the mask blank 110, a resist film of an organic material is preferably formed in contact with a surface of the hard mask film 9 at a film thickness of 100 nm or less.

As mentioned above, the mask blank 110 of the second embodiment includes an etching stopper film 2 containing hafnium, aluminum, and oxygen between the transparent substrate 1 and the light shielding film 8 which is a thin film for pattern formation, and a ratio by atom % of the hafnium content to a total content of hafnium and aluminum in the etching stopper film 2 is 0.86 or less. The etching stopper film 2 simultaneously satisfies the properties of having higher durability to dry etching with fluorine-based gas performed in forming a pattern in the light shielding film 8 and having a higher transmittance to an exposure light compared to an etching stopper film formed of hafnium oxide. Accordingly, since over etching can be made without digging a main surface of the transfer substrate 1 in forming a transfer pattern in the light shielding film 8 by dry etching with fluorine-based gas, verticality of the pattern sidewall can be enhanced, and in-plane CD uniformity of the pattern can be enhanced.

On the other hand, when a transfer mask (binary mask) 210 was manufactured from the mask blank 110 of the second embodiment, since the etching stopper film 2 has a higher transmittance to an exposure light than conventional etching stopper films, a transmittance of a transmitting portion where the light shielding film 8 is removed is enhanced. Accordingly, a contrast is enhanced between the light shielding portion where an exposure light is shielded by the pattern of the light shielding film 8 and the transmitting portion where an exposure light passes the etching stopper film 2. Therefore, a high pattern resolution can be obtained when the transfer mask is used to exposure-transfer a resist film on a semiconductor substrate. Incidentally, the mask blank 110 of the second embodiment is applicable as a mask blank for manufacturing a dug-down Levenson type phase shift mask or a CPL (Chromeless Phase Lithography) mask.

### [Transfer Mask and its Manufacture]

The transfer mask 210 (see FIG. 5) of the second embodiment is featured in that the etching stopper film 2 of the mask blank 110 is left on the entire main surface of the transparent substrate 1, and a transfer pattern (light shielding pattern 8a) is formed in the light shielding film 8. In the case where a hard mask film 9 is provided on the mask blank 110, the hard mask film 9 is removed during manufacture of the transfer mask 210.

Namely, the transfer mask 210 of the second embodiment is featured in having a structure where an etching stopper film 2 and a thin film which is a light shielding film having a transfer pattern (light shielding pattern 8a) are stacked in this order on a transparent substrate 1, the light shielding pattern 8a is formed of a material containing silicon, the etching stopper film 2 is formed of a material containing hafnium, aluminum, and oxygen, and a ratio by atom % of hafnium content to a total amount of hafnium and aluminum in the etching stopper film 2 is 0.86 or less.

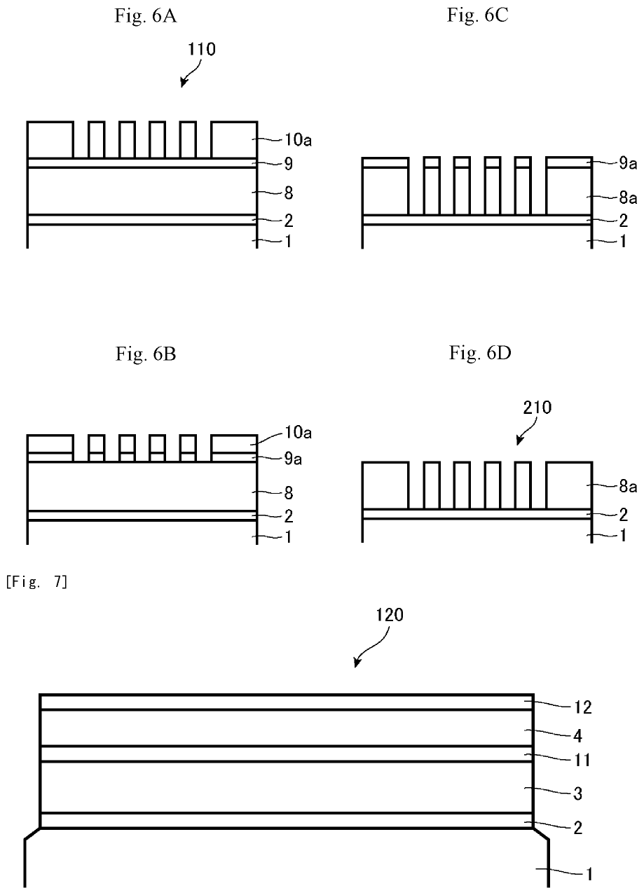

The manufacturing method of the transfer mask (binary mask) 210 of the second embodiment is featured in using the mask blank 110, and including the step of forming a transfer pattern in the light shielding film 8 by dry etching using fluorine-based gas. The method of manufacturing the transfer mask 210 according to the second embodiment is explained below according to the manufacturing steps shown in FIGS. 6A-6D. Explained herein is the method of manufacturing the transfer mask 210 using the mask blank 110 having the hard mask film 9 stacked on the light shielding film 8. Further, an explanation is made in the case of applying a material containing a transition metal and silicon to the light shielding film 8, and applying a material containing chromium to the hard mask film 9.

First, a resist film is formed in contact with the hard mask film 9 of the mask blank 110 by spin coating. Next, a transfer pattern (light shielding pattern) to be formed in the light shielding film 8 was written with an electron beam in the resist film, and a predetermined treatment such as developing was conducted, to thereby form a resist pattern 10a having a light shielding pattern (see FIG. 6A). Subsequently, dry etching is carried out using mixed gas of chlorine-based gas and oxygen gas with the resist pattern 10a as a mask, and a transfer pattern (hard mask pattern 9a) is formed in the hard mask film 9 (see FIG. 6B).

Next, after removing the resist pattern 10a, dry etching is conducted using fluorine-based gas with the hard mask pattern 9a as a mask, and a transfer pattern (light shielding pattern 8a) is formed in the light shielding film 8 (see FIG. 6C). In dry etching of the light shielding film 8 with fluorine-based gas, an additional etching (over etching) is done to enhance verticality of the sidewall of the pattern of the light shielding pattern 8a and to enhance in-plane CD uniformity of the light shielding pattern 8a. Even after the over etching, a surface of the etching stopper film 2 is only slightly etched and a surface of the transparent substrate 1 is not exposed at the transmitting portion of the light shielding pattern 8a.

Further, the remaining hard mask pattern 9a is removed by dry etching using mixed gas of chlorine-based gas and oxygen gas, and through predetermined treatments such as cleaning, a transfer mask 210 is obtained (see FIG. 6D). While SC-1 cleaning was used in the cleaning step, variation was observed in the film reduction amount of the etching stopper film 2 depending on Hf/[Hf+Al] ratio as shown in the Examples and Comparative Examples given below. Incidentally, chlorine-based gas and fluorine-based gas used in the aforementioned dry etching are similar to those used in the first embodiment.

The transfer mask 210 of the second embodiment is manufactured using the mask blank 110 mentioned above. The etching stopper film 2 simultaneously satisfies the properties of having high durability to dry etching with fluorine-based gas performed in forming a pattern in the light shielding film 8 and having a high transmittance to an exposure light compared to an etching stopper film formed of hafnium oxide. Accordingly, over etching can be done without digging a main surface of the transparent substrate 1 in forming the light shielding pattern (transfer pattern) 8a in the light shielding film 8 by dry etching using fluorine-based gas. Therefore, the transfer mask 210 of the second embodiment has high verticality of the sidewall of the light shielding pattern 8a and high in-plane CD uniformity of the light shielding pattern 8a.

On the other hand, since the etching stopper film 2 of the transfer mask 210 of the second embodiment has a higher transmittance to an exposure light than conventional etching stopper films, a transmittance of a transmitting portion where the light shielding film 8 is removed is enhanced. Accordingly, a contrast is enhanced between the light shielding portion where an exposure light is shielded by the pattern of the light shielding film 8 and the transmitting portion where an exposure light passes the etching stopper film 2. Therefore, a high pattern resolution can be obtained when the transfer mask is used to exposure-transfer a resist film on a semiconductor substrate.

### [Manufacture of Semiconductor Device]

The method of manufacturing a semiconductor device according to the second embodiment is featured in that a transfer pattern is exposure-transferred to a resist film on a semiconductor substrate using the transfer mask 210 of the second embodiment or the transfer mask 210 manufactured by using the mask blank 110 of the second embodiment. The transfer mask 200 of the second embodiment has high verticality of the sidewall of the light shielding pattern 8a and high in-plane CD uniformity of the light shielding pattern 8a. Therefore, when an exposure transfer is made on a resist film on a semiconductor device using the transfer mask 210 of the second embodiment, a pattern can be formed in the resist film on the semiconductor device at a precision sufficiently satisfying the design specification.

Further, since the etching stopper film 2 of the transfer mask 210 of the second embodiment has a higher transmittance to an exposure light than conventional etching stopper films, a transmittance of a transmitting portion where the light shielding film 8 is removed is enhanced. Accordingly, a contrast is enhanced between the light shielding portion where an exposure light is shielded by the pattern of the light shielding film 8 and the transmitting portion where an exposure light passes the etching stopper film 2. Therefore, a high pattern resolution can be obtained when the transfer mask is used to exposure-transfer a resist film on a semiconductor substrate. Therefore, a high pattern resolution can be obtained when the transfer mask 210 is used to exposure-transfer a resist film on a semiconductor substrate. In the case where a film to be processed is dry etched to form a circuit pattern using this resist pattern as a mask, a highly precise and high-yield circuit pattern can be formed without short-circuit of wiring and disconnection caused by lack of precision and transfer defect.

### Third Embodiment

### [Mask Blank and its Manufacture]

A mask blank 120 (see FIG. 7) according to a third embodiment of this disclosure has a mask blank structure explained in the first embodiment provided with a hard mask film 11 between a phase shift film 3 and a light shielding film 4, and a hard mask film 12 on the light shielding film 4. The light shielding film 4 according to this embodiment contains at least one or more elements selected from silicon and tantalum, and the hard mask films 11, 12 contain chromium. The mask blank 120 according to the third embodiment is particularly preferable for the purpose of manufacturing a CPL (Chromeless Phase Lithography) mask. Incidentally, in the case where the mask blank 120 of the third embodiment is for the purpose of manufacturing a CPL mask, a transmittance of the phase shift film 3 to an exposure light is preferably 90% or more, and more preferably 92% or more.

The phase shift film 3 of the third embodiment is preferably formed of a material containing silicon and oxygen. The phase shift film 3 preferably has a total silicon and oxygen content of 95 atom % or more. The oxygen content of the phase shift film 3 is preferably 60 atom % or more. The thickness of the phase shift film 3 is preferably 210 nm or less, more preferably 200 nm or less, and even more preferably 190 nm or less. Further, the thickness of the phase shift film 3 is preferably 150 nm or more, and more preferably 160 nm or more. A refractive index n of the phase shift film 3 to an ArF exposure light is preferably 1.52 or more, and more preferably 1.54 or more. Further, a refractive index n of the phase shift film 3 is preferably 1.68 or less, and more preferably 1.63 or less. An extinction coefficient k to an ArF excimer laser exposure light of the phase shift film 3 is preferably 0.02 or less, and more preferably close to 0.

On the other hand, the phase shift film 3 can be formed of a material containing silicon, oxygen, and nitrogen. In this case, a transmittance of the phase shift film 3 to an exposure light is preferably 70% or more, and more preferably 80% or more. The total content of silicon, oxygen, and nitrogen of the phase shift film 3 is preferably 95 atom % or more. Oxygen content of the phase shift film 3 is preferably 40 atom % or more. Oxygen content of the phase shift film 3 is preferably 60 atom % or less. Nitrogen content of the phase shift film 3 is preferably 7 atom % or more. Nitrogen content of the phase shift film 3 is preferably 20 atom % or less.

In this case, the thickness of the phase shift film 3 is preferably 150 nm or less, and more preferably 140 nm or less. Further, the thickness of the phase shift film 3 is preferably 100 nm or more, and more preferably 110 nm or more. A refractive index n of the phase shift film 3 to an ArF exposure light is preferably 1.70 or more, and more preferably 1.75 or more. Further, a refractive index n of the phase shift film 3 is preferably 2.00 or less, and more preferably 1.95 or less. An extinction coefficient k of the phase shift film 3 to an ArF excimer laser exposure light is preferably 0.05 or less, and more preferably 0.03 or less.

### [Transfer Mask and its Manufacture]

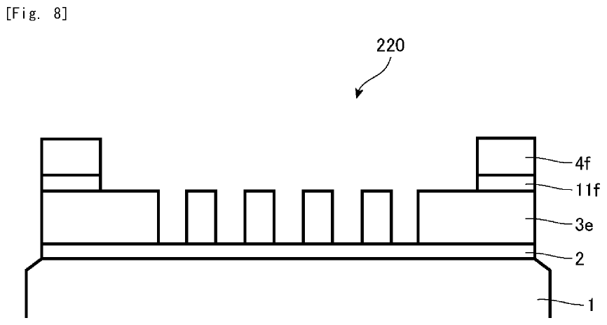

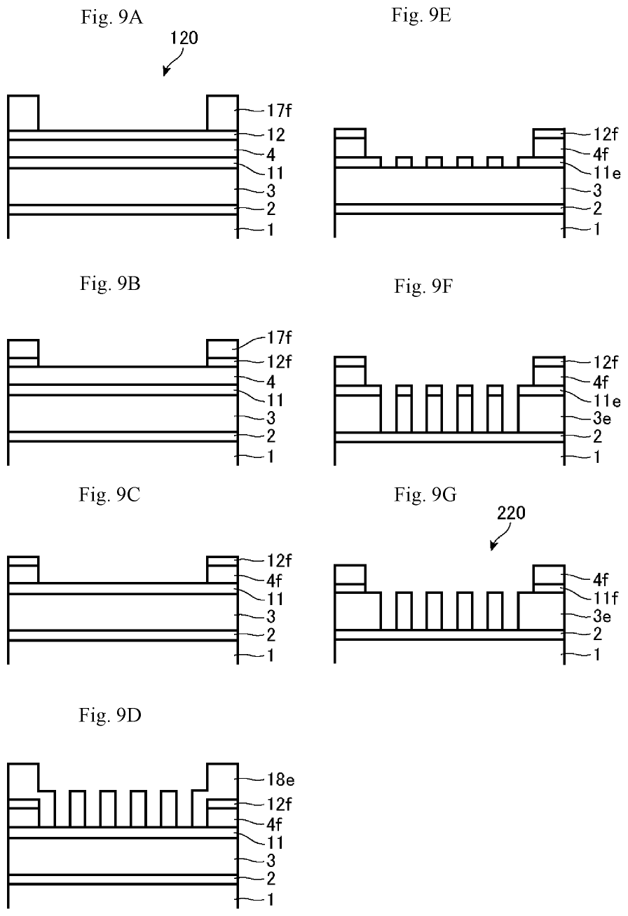

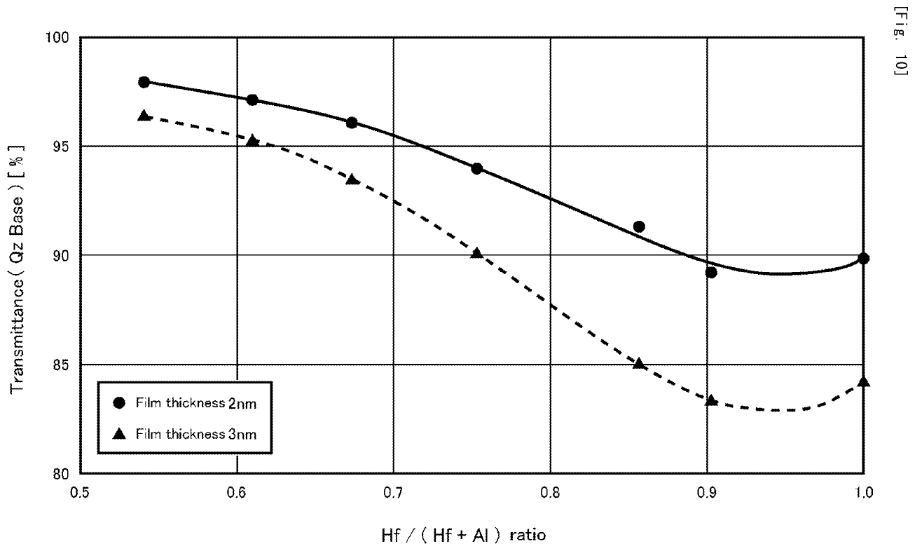

The transfer mask 220 (see FIG. 8) of the third embodiment is featured in that the mask is a CPL mask, a type of a phase shift mask, the etching stopper film 2 of the mask blank 120 is left on the entire main surface of the transparent substrate 1, a phase shift pattern 3e is formed in the phase shift film 3, the hard mask pattern 11f is formed in the hard mask film 11, and a light shielding pattern 4f is formed in the light shielding film 4. The hard mask film 12 is removed during manufacture of the transfer mask 220 (see FIGS. 9A-9G).

Namely, the transfer mask 220 according to the third embodiment has a structure where the etching stopper film 2, the phase shift pattern 3e, the hard mask pattern 11f, and the light shielding pattern 4f are stacked in this order on the transparent substrate 1, the phase shift pattern 3e is formed of a material containing silicon and oxygen, the hard mask pattern 11f is formed of a material containing chromium, and the light shielding film 4 is formed of a material containing at least one or more elements selected from silicon and tantalum.

The method of manufacturing the transfer mask 220 of the third embodiment uses the mask blank 120 mentioned above, which is featured in including the steps of forming a light shielding pattern in the hard mask film 12 by dry etching using chlorine-based gas; forming a light shielding pattern 4f in the light shielding film 4 by dry etching using fluorine-based gas with the hard mask film (hard mask pattern) 12f having the light shielding pattern as a mask; forming a phase shift pattern in the hard mask film 11 by dry etching using chlorine-based gas; forming a phase shift pattern 3e in the phase shift film 3 by dry etching using fluorine-based gas with a hard mask film (hard mask pattern) 11e having a phase shift pattern as a mask; and forming a hard mask pattern 11f in the hard mask film 11 by dry etching using chlorine-based gas with the light shielding pattern 4f as a mask (see FIGS. 9A-9G).

The method of manufacturing the transfer mask 220 according to the third embodiment is explained according to the manufacturing steps shown in FIGS. 9A-9G. Described herein is the case where a material containing silicon is applied to the light shielding film 4.

First, a resist film is formed in contact with the hard mask film 12 of the mask blank 120 by spin coating. Next, a light shielding pattern to be formed in the light shielding film 4 is written on the resist film with an electron beam, and predetermined treatments such as developing are further conducted to thereby form a resist pattern 17f (see FIG. 9A). Subsequently, dry etching is carried out using mixed gas of chlorine-based gas and oxygen gas with the resist pattern 17f as a mask, and a hard mask pattern 12f is formed in the hard mask film 12 (see FIG. 9B).

Next, after removing the resist pattern 17f, dry etching is conducted using fluorine-based gas such as CF₄ with the hard mask pattern 12f as a mask, and a light shielding pattern 4f is formed in the light shielding film 4 (see FIG. 9C).

Subsequently, a resist film is formed by spin coating, and thereafter, a phase shift pattern which should be formed in the phase shift film 3 is written with an electron beam in the resist film, and predetermined treatments such as developing are further conducted, to thereby form a resist pattern 18e (see FIG. 9D).

Next, dry etching is carried out using mixed gas of chlorine-based gas and oxygen gas with the resist pattern 18e as a mask, and a hard mask pattern 11e is formed in the hard mask film 11 (see FIG. 9E). Next, after removing the resist pattern 18e, dry etching is carried out using fluorine-based gas such as CF₄, and a phase shift pattern 3e is formed in the phase shift film 3 (see FIG. 9F).

Subsequently, dry etching is conducted using mixed gas of chlorine-based gas and oxygen gas with the light shielding pattern 4f as a mask, and a hard mask pattern 11f is formed. At this stage, the hard mask pattern 12f is removed simultaneously.

Thereafter, a cleaning step is conducted and a mask defect inspection is performed as necessary. Further, depending on the result of the defect inspection, a defect repair is carried out as necessary and the transfer mask 220 is manufactured. While SC-1 cleaning was used in the cleaning step, variation was observed in the film reduction amount of the etching stopper film 2 depending on Hf/[Hf+Al] ratio as shown in the Examples and Comparative Examples given below.

The transfer mask (CPL mask) 220 of the third embodiment was manufactured using the mask blank 120 mentioned above. Therefore, the transfer mask 220 of the third embodiment has high verticality of the sidewall of the phase shift pattern 3e and high in-plane CD uniformity of the phase shift pattern 3e. Each structure including the phase shift pattern 3e and a bottom surface of the etching stopper film 2 has significantly high in-plane uniformity in the height direction (thickness direction). Therefore, the transfer mask 220 has high in-plane uniformity in phase shift effect.

On the other hand, the etching stopper film 2 of the CPL mask 220 of the third embodiment has a higher transmittance to an exposure light than conventional etching stopper films. Therefore, each transmittance of a phase shift portion where the phase shift film 3 remains and a transmitting portion where the phase shift film 3 is removed is enhanced. Accordingly, a phase shift effect is enhanced between an exposure light that transmitted through the pattern of the phase shift film 3 and the etching stopper film 2, and an exposure light that transmitted through only the etching stopper film 2. Therefore, a high pattern resolution can be obtained when the CPL mask 220 was used to exposure-transfer a resist film on a semiconductor substrate.

### [Manufacture of Semiconductor Device]

The method of manufacturing a semiconductor device according to the third embodiment is featured in that a transfer pattern is exposure-transferred in a resist film on a semiconductor substrate using the transfer mask (CPL mask) 220 of the third embodiment or the transfer mask (CPL mask) 220 manufactured by using the mask blank 120 of the third embodiment. The transfer mask 220 of the third embodiment has high verticality of the sidewall of the phase shift pattern 3e, high in-plane CD uniformity of the phase shift pattern 3e, and high in-plane uniformity of phase shift effect. Therefore, when an exposure transfer is made on a resist film on a semiconductor device using the transfer mask 220 of the third embodiment, a pattern can be formed in the resist film on the semiconductor device at a precision sufficiently satisfying the design specification.

Further, the etching stopper film 2 of the transfer mask 220 of the third embodiment has a higher transmittance to an exposure light than conventional etching stopper films. Therefore, each transmittance of a phase shift portion where the phase shift film 3 remains and a transmitting portion where the phase shift film 3 is removed is enhanced. Accordingly, a phase shift effect is enhanced between an exposure light that transmitted through the pattern of the phase shift film 3 and the etching stopper film 2, and an exposure light that transmitted through only the etching stopper film 2. Therefore, a high pattern resolution can be obtained when the transfer mask 220 was used to exposure-transfer a resist film on a semiconductor substrate. In the case where a film to be processed was dry etched to form a circuit pattern using this resist pattern as a mask, a highly precise and high-yield circuit pattern can be formed without short-circuit of wiring and disconnection caused by lack of precision and transfer defect.

On the other hand, the material constructing the etching stopper film 2 of this disclosure is applicable as a material constructing a protective film provided on an alternative form of mask blank for manufacturing a reflective mask for EUV lithography which applies an extreme ultra violet (hereafter EUV) as an exposure light source. Namely, the alternative form of mask blank has a structure where a multilayer reflective film, a protective film, and an absorber film are stacked in this order on a substrate, the protective film is formed of a material containing hafnium, aluminum, and oxygen, and a ratio by atom % of an amount of the hafnium to a total amount of the hafnium and the aluminum in the protective film is 0.60 or more and 0.86 or less. Incidentally, an EUV light indicates light of a wavelength range of soft x-ray region or vacuum ultraviolet region, specifically, a light having a wavelength of around 0.2 to 100 nm.

The configuration of the etching stopper film 2 of this disclosure given above can be applied as the configuration of the protective film of the mask blank of the alternative form of mask blank. Such a protective film has high durability to both of dry etching with fluorine-based gas and dry etching with chlorine-based gas. Therefore, not only a material containing tantalum, but various materials can be applied to the absorber film. For example, any of a material containing chromium, a material containing silicon, and a material containing a transition metal can be used for the absorber film.

The substrate can be made from materials such as synthetic quartz glass, quartz glass, aluminosilicate glass, soda-lime glass, low thermal expansion glass (SiO₂—TiO₂ glass, etc.), crystallized glass where β-quartz solid solution is precipitated, single crystal silicon, and SiC.

The multilayer reflective film is a multilayer film where a multiple of single cycles is stacked, the single cycle including a stack of a low refractive index layer of a low refractive index material with a low refractive index to an EUV light and a high refractive index layer of a high refractive index material with a high refractive index to an EUV light. Generally, the low refractive index layer is formed of a light element or a compound thereof, and the high refractive index layer is formed of a heavy element or a compound thereof. The multilayer reflective film preferably has 20 to 60 cycles, and more preferably 30 to 50 cycles. In the case of applying an EUV light of 13-14 nm wavelength as an exposure light, a multilayer film with a Mo layer and a Si layer stacked alternately for 20 to 60 cycles can be preferably used as the multilayer reflective film. In addition to the above, the multilayer reflective film applicable to an EUV light includes Si/Ru cycle multilayer film, Be/Mo cycle multilayer film, Si compound/Mo compound cycle multilayer film, Si/Nb cycle multilayer film, Si/Mo/Ru cycle multilayer film, Si/Mo/Ru/Mo cycle multilayer film, Si/Ru/Mo/Ru cycle multilayer film, etc. Depending on the wavelength range of an EUV light to be applied, material and film thickness of each layer can be selected arbitrarily. The multilayer reflective film is preferably made by sputtering method (DC sputtering, RF sputtering, ion beam sputtering, etc.). Particularly, it is preferable to apply ion beam sputtering that can easily control film thickness.

A reflective mask can be manufactured from the alternative form of mask blank. Namely, the alternative form of reflective mask is a mask blank having a structure where a multilayer reflective film, a protective film, and an absorber film are stacked in this order on a substrate, the absorber film includes a transfer pattern, the protective film is formed of a material containing hafnium, aluminum, and oxygen, and a ratio by atom % of an amount of the hafnium to a total amount of the hafnium and the aluminum in the protective film is 0.60 or more and 0.86 or less.

### Example 1

The embodiment of this disclosure is described in greater detail below together with examples, referring to FIGS. 7 to 9G.

### Example 1

### [Manufacture of Mask Blank]

A transparent substrate 1 formed of a synthetic quartz glass with a size of a main surface of about 152 mm×about 152 mm and a thickness of about 6.35 mm was prepared. An end surface and the main surface of the transparent substrate 1 were polished to a predetermined surface roughness or less (0.2 nm or less root mean square roughness Rq), and thereafter subjected to predetermined cleaning treatment and drying treatment.

Next, an etching stopper film 2 formed of hafnium, aluminum, and oxygen (HfAlO film) was formed in contact with a surface of the transparent substrate 1 at a thickness of 3 nm. Concretely, the etching stopper film 2 was formed by placing the transparent substrate 1 in a single-wafer RF sputtering apparatus, simultaneously discharging an Al₂O₃ target and an HfO₂ target, and by sputtering (RF sputtering) using argon (Ar) gas as sputtering gas. An etching stopper film formed on another transparent substrate under the same conditions was analyzed by X-ray photoelectron spectroscopy, and the result was Hf:Al:O=33.0:5.4:61.6 (atom % ratio). Namely, Hf/[Hf+Al] ratio of the etching stopper film 2 is 0.86. Incidentally, each optical characteristic of the etching stopper film was measured using the spectroscopic ellipsometer (M-2000D manufactured by J.A. Woollam), and a refractive index n was 2.854 and an extinction coefficient k was 0.279 in a light of 193 nm wavelength.

Next, a phase shift film (SiO₂ film) 3 including silicon and oxygen was formed in contact with a surface of the etching stopper film 2 at a thickness of 177 nm. Concretely, the transparent substrate 1 having the etching stopper film 2 formed thereon was placed in a single-wafer RF sputtering apparatus, and by reactive sputtering (RF sputtering) using a silicon dioxide (SiO₂) target and argon (Ar) gas as sputtering gas, the phase shift film 3 was formed.

Optical characteristics of a phase shift film formed on another transparent substrate under the same conditions and subjected to heat treatment were measured using a spectroscopic ellipsometer (M-2000D manufactured by J. A. Woollam), and a refractive index n was 1.563 and an extinction coefficient k was 0.000 (lower limit measurable) at a light of 193 nm wavelength.

Next, a hard mask film (CrN film) 11 including chromium and nitrogen was formed in contact with a surface of the phase shift film 3 at a thickness of 5 nm.

Concretely, the hard mask film 11 was formed by placing the transparent substrate 1 after the heat treatment in a single-wafer DC sputtering apparatus, and by reactive sputtering (DC sputtering) using a chromium (Cr) target, with mixed gas of argon (Ar), nitrogen (N₂), and helium (He) as sputtering gas. A hard mask film formed on another transparent substrate under the same conditions was analyzed by X-ray photoelectron spectroscopy, and the result was Cr:N=75:25 (atom % ratio).

Next, a light shielding film (SiN film) 4 including silicon and nitrogen was formed in contact with a surface of the hard mask film 11 at a thickness of 48 nm. Concretely, the light shielding film 4 was formed by placing the transparent substrate 1 after the heat treatment in a single-wafer RF sputtering apparatus, and by reactive sputtering (RF sputtering) using a silicon (Si) target with mixed gas of argon (Ar), nitrogen (N₂), and helium (He) as sputtering gas. A light shielding film formed on another transparent substrate under the same conditions was analyzed by X-ray photoelectron spectroscopy, and the result was Si:N:O=75.5:23.2:1.3 (atom % ratio). Incidentally, the stacked structure of the phase shift film 3, the hard mask film 11, and the light shielding film 4 had an optical density of 2.8 or more to an ArF excimer laser wavelength (193 nm).

Next, a hard mask film (CrN film) 12 including chromium and nitrogen was formed in contact with a surface of the light shielding film 4 at a thickness of 5 nm. Concrete configuration and manufacturing method of the hard mask film 12 are similar to the hard mask film 11 given above. A mask blank 120 of Example 1 was manufactured through the above procedure.

A transmittance of an etching stopper film formed on another transparent substrate at a film thickness of 3 nm in a wavelength of an ArF excimer laser (193 nm) was measured using the phase shift measuring apparatus, and a transmittance was 85.0% when a transmittance of the transparent substrate is 100%. From this result, it was found that an influence of reduction in a transmittance caused by providing the etching stopper film of Example 1 is small. Further, a transmittance of an etching stopper film formed on another transparent substrate at a film thickness of 2 nm in a wavelength of an ArF excimer laser (193 nm) was measured using the phase shift measuring apparatus, and a transmittance was 91.3% when a transmittance of the transparent substrate is 100%. Further, a transparent substrate having the etching stopper film formed thereon was subjected to spin cleaning described below using a cleaning liquid of a mixed solution of ammonia water, hydrogen peroxide, and deionized water referred to as SC-1 cleaning. In SC-1 cleaning by spin cleaning method, the cleaning liquid is dropped around the rotational center of the mask blank 120 rotated at a low speed, the cleaning liquid is spread by rotation, and the cleaning liquid is piled up on the entire surface of the mask blank 120. Cleaning is continued thereafter by rotating the mask blank 120 at a low speed while keeping on supplying the cleaning liquid until the end of the cleaning time, and after the end of the cleaning time, pure water is supplied so that the cleaning liquid is replaced by pure water and finally spin-dried. The film reduction amount was 0.35 nm in the etching stopper film measured after ten times the cleaning step. From this result, it was confirmed that the etching stopper film 2 of Example 1 has sufficient resistance to chemical cleaning performed during manufacturing a phase shift mask from a mask blank.

An etching stopper film formed on another transparent substrate was subjected to dry etching using mixed gas of SF₆ and He as etching gas, and the film reduction amount of the etching stopper film measured was 0.54 nm.

### [Manufacture of Phase Shift Mask]

Next, a phase shift mask (CPL mask) 220 of Example 1 was manufactured through the following procedure using the mask blank 120 of Example 1. First, a resist film of a chemically amplified resist for electron beam writing was formed in contact with a surface of the hard mask film 12 by spin coating at a film thickness of 150 nm. Next, a light shielding pattern including a light shielding band to be formed in the light shielding film 4 was written on the resist film by an electron beam, and a predetermined development treatment was conducted to thereby form a resist pattern 17f having a light shielding pattern (see FIG. 9A).

Next, dry etching was conducted using mixed gas of chlorine and oxygen (gas flow ratio Cl₂:O₂=4:1) with the resist pattern 17f as a mask, and a pattern (hard mask pattern 12f) was formed in the hard mask film 12 (see FIG. 9B). Next, the resist pattern 17f was removed by TMAH. Next, dry etching was conducted using fluorine-based gas (SF₆+He) with the hard mask pattern 12f as a mask, and a pattern (light shielding pattern 4f) including a light shielding band was formed in the light shielding film 4 (see FIG. 9C).

Next, a resist film of a chemically amplified resist for electron beam writing was formed on the light shielding pattern 4f and the hard mask film 11 by spin coating at a film thickness of 80 nm. Next, a transfer pattern, which is a pattern that should be formed in the phase shift film 3, was written in the resist film, and a predetermined treatment such as developing was further conducted, to thereby form a resist pattern 18e having a transfer pattern (see FIG. 9D).

Next, dry etching was conducted using mixed gas of chlorine and oxygen (gas flow ratio Cl₂:O₂=15:1) with the resist pattern 18e as a mask, and a transfer pattern (hard mask pattern 11e) was formed in the hard mask film 11 (see FIG. 9E). Next, after removing the resist pattern 18e by TMAH, dry etching was conducted using fluorine-based gas (SF₆+He) with the hard mask pattern 11e as a mask, and a transfer pattern (phase shift pattern 3e) was formed in the phase shift film 3 (see FIG. 9F). In the dry etching with fluorine-based gas, in addition to the etching time from the start of etching of the phase shift film 3 until the etching advances in the thickness direction of the phase shift film 3 and a surface of the etching stopper film 2 starts exposing (just etching time), an additional etching (over etching) was performed for 20% of the time of the just etching time (over etching time). Incidentally, bias was applied at 25 W power in the dry etching with fluorine-based gas, under so-called high bias etching condition.

Next, dry etching was conducted using mixed gas of chlorine and oxygen (gas flow ratio Cl₂:O₂=4:1) with the light shielding pattern 4f as a mask, and a pattern (hard mask pattern 11f) was formed in the hard mask film 11. At this stage, the hard mask pattern 12f was removed simultaneously. Further, predetermined treatments such as SC-1 cleaning were carried out, and the phase shift mask 220 was obtained (see FIG. 9G).

Next, using another mask blank, a phase shift mask was manufactured through the same procedure. In-plane CD uniformity of the phase shift pattern was inspected, obtaining a good result. The cross section of the phase shift pattern was observed using STEM (Scanning Transmission Electron Microscopy), and verticality of the sidewall of the phase shift pattern was high, digging of the etching stopper film was as slight as less than 1 nm, and there was no occurrence of micro trench.

On the phase shift mask (CPL mask) 220 of Example 1, a simulation of a transfer image was made when an exposure transfer was made on a resist film on a semiconductor device at an exposure light of 193 nm wavelength, using AIMS193 (manufactured by Carl Zeiss). The simulated exposure transfer image was inspected, and the design specification was fully satisfied. There was little influence on the exposure transfer caused by the reduction of a transmittance of the transparent portion by providing the etching stopper film 2. It can be considered from this result that a circuit pattern to be finally formed on the semiconductor device can be formed at a high precision, even if the phase shift mask 220 of Example 1 was set on a mask stage of an exposure apparatus and a resist film on the semiconductor device was subjected to an exposure transfer.

### Example 2

### [Manufacture of Mask Blank]

A mask blank 120 of Example 2 was manufactured through the same procedure as the mask blank of Example 1, except for the etching stopper film 2. Explanation is made below on the points that differ from the mask blank of Example 1.

In the etching stopper film 2 of Example 2, a HfAlO film (Hf:Al:O=28.7:9.2:62.1 (atom % ratio)) including hafnium, aluminum, and oxygen was applied, which was formed in contact with a surface of the transparent substrate 1 at a thickness of 3 nm. Namely, Hf/[Hf+Al] of the etching stopper film 2 is 0.75. Further, a refractive index n of the etching stopper film 2 to a light of 193 nm wavelength is 2.642, and an extinction coefficient k is 0.186.

A transmittance of an etching stopper film formed on another transparent substrate at a film thickness of 3 nm in a wavelength of an ArF excimer laser (193 nm) was measured using the phase shift measuring apparatus, and a transmittance was 90.1% when a transmittance of the transparent substrate is 100%. From this result, it was found that an influence of reduction in a transmittance caused by providing the etching stopper film of Example 2 is small. Further, a transmittance of an etching stopper film formed on another transparent substrate at a film thickness of 2 nm in a wavelength of an ArF excimer laser (193 nm) was measured using the phase shift measuring apparatus, and a transmittance was 93.8% when a transmittance of the transparent substrate is 100%. The film reduction amount was 0.53 nm in the etching stopper film measured after ten times the cleaning step on the transparent substrate on which the etching stopper film was formed through SC-cleaning explained in Example 1. From this result, it was confirmed that the etching stopper film 2 of Example 2 has sufficient resistance to chemical cleaning performed during manufacturing a phase shift mask from a mask blank.

An etching stopper film formed on another transparent substrate was subjected to dry etching using mixed gas of SF₆ and He as etching gas under the same condition as Example 1, and the film reduction amount of the etching stopper film measured was 0.44 nm.

### [Manufacture of Phase Shift Mask]

Next, a phase shift mask 220 of Example 2 was manufactured through the same procedure as Example 1 using the mask blank 120 of Example 2. Next, using another mask blank, a phase shift mask was manufactured through the same procedure. In-plane CD uniformity of the phase shift pattern was inspected, obtaining a good result. The cross section of the phase shift pattern was observed using STEM, and verticality of the sidewall of the phase shift pattern was high, digging of the etching stopper film was as slight as less than 1 nm, and there was no occurrence of micro trench.

On the phase shift mask (CPL mask) 220 of Example 2, a simulation of a transfer image was made when an exposure transfer was made on a resist film on a semiconductor device at an exposure light of 193 nm wavelength, using AIMS193 (manufactured by Carl Zeiss). The simulated exposure transfer image was inspected, and the design specification was fully satisfied. There was little influence on the exposure transfer caused by the reduction of transmittance of the transparent portion by providing the etching stopper film 2. It can be considered from this result that a circuit pattern to be finally formed in the semiconductor device can be formed at a high precision, even if the phase shift mask 220 of Example 2 was set on a mask stage of an exposure apparatus and a resist film on the semiconductor device was subjected to an exposure transfer.

### Example 3

### [Manufacture of Mask Blank]

The mask blank 120 of Example 3 was manufactured through the same procedure as the mask blank of Example 1, except for the etching stopper film 2. In the etching stopper film 2 of Example 3, a HfAlO film (Hf:Al:O=25.3:12.3:62.4 (atom % ratio)) including hafnium, aluminum, and oxygen was applied, which was formed in contact with a surface of the transparent substrate 1 at a thickness of 3 nm. Namely, Hf/[Hf+Al] of the etching stopper film 2 is 0.67. Further, a refractive index n of the etching stopper film 2 to a light of 193 nm wavelength is 2.438, and an extinction coefficient k is 0.108.

A transmittance of an etching stopper film formed on another transparent substrate at a film thickness of 3 nm in a wavelength of an ArF excimer laser (193 nm) was measured using the phase shift measuring apparatus, and a transmittance was 93.4% when a transmittance of the transparent substrate is 100%. From this result, it was found that an influence of reduction in a transmittance caused by providing the etching stopper film of Example 3 is small. Further, a transmittance of an etching stopper film formed on another transparent substrate at a film thickness of 2 nm in a wavelength of an ArF excimer laser (193 nm) was measured using the phase shift measuring apparatus, and a transmittance was 96.1 when a transmittance of the transparent substrate is 100%. The film reduction amount was 0.70 nm in the etching stopper film measured after ten times the cleaning step on the transparent substrate on which the etching stopper film was formed through SC-1 cleaning explained in Example 1. From this result, it was confirmed that the etching stopper film 2 of Example 3 has sufficient resistance to chemical cleaning performed during manufacturing a phase shift mask from a mask blank.

An etching stopper film formed on another transparent substrate was subjected to dry etching using mixed gas of SF₆ and He as etching gas under the same condition as Example 1, and the film reduction amount of the etching stopper film measured was 0.37 nm.

### [Manufacture of Phase Shift Mask]

Next, a phase shift mask 220 of Example 3 was manufactured through the same procedure as Example 1 using the mask blank 120 of Example 3. Using another mask blank, a phase shift mask was manufactured through the same procedure. In-plane CD uniformity of the phase shift pattern was inspected, obtaining a good result. The cross section of the phase shift pattern was observed using STEM, and verticality of the sidewall of the phase shift pattern was high, digging of the etching stopper film was as slight as about 1 nm, and there was no occurrence of micro trench.

On the phase shift mask (CPL mask) 220 of Example 3, a simulation of a transfer image was made when an exposure transfer was made on a resist film on a semiconductor device at an exposure light of 193 nm wavelength, using AIMS193 (manufactured by Carl Zeiss). The simulated exposure transfer image was inspected, and the design specification was fully satisfied. There was little influence on the exposure transfer caused by the reduction of a transmittance of the transparent portion by providing the etching stopper film 2. It can be considered from this result that a circuit pattern to be finally formed on the semiconductor device can be formed at a high precision, even if the phase shift mask 220 of Example 3 was set on a mask stage of an exposure apparatus and a resist film on the semiconductor device was subjected to an exposure transfer.

### Example 4

### [Manufacture of Mask Blank]

The mask blank 120 of Example 4 was manufactured through the same procedure as the mask blank of Example 1, except for the etching stopper film 2. In the etching stopper film 2 of Example 4, a HfAlO film (Hf:Al:O=22.6:14.5:62.9 (atom % ratio)) including hafnium, aluminum, and oxygen was applied, which was formed in contact with a surface of the transparent substrate 1 at a thickness of 3 nm. Namely, Hf/[Hf+Al] of the etching stopper film 2 is 0.61. Further, a refractive index n of the etching stopper film 2 to a light of 193 nm wavelength is 2.357, and an extinction coefficient k is 0.067.

A transmittance of an etching stopper film formed on another transparent substrate at a film thickness of 3 nm in a wavelength of an ArF excimer laser (193 nm) was measured using the phase shift measuring apparatus, and a transmittance was 95.3% when a transmittance of the transparent substrate is 100%. From this result, it was found that an influence of reduction in a transmittance caused by providing the etching stopper film of Example 3 is small. Further, a transmittance of an etching stopper film formed on another transparent substrate at a film thickness of 2 nm in a wavelength of an ArF excimer laser (193 nm) was measured using the phase shift measuring apparatus, and a transmittance was 97.2% when a transmittance of the transparent substrate is 100%. The film reduction amount was 0.93 nm in the etching stopper film measured after ten times the cleaning step on the transparent substrate on which the etching stopper film was formed through SC-cleaning explained in Example 1. From this result, it was confirmed that the etching stopper film 2 of Example 4 has sufficient resistance to chemical cleaning performed during manufacturing a phase shift mask from a mask blank.

An etching stopper film formed on another transparent substrate was subjected to dry etching using mixed gas of SF₆ and He as etching gas under the same condition as Example 1, and the film reduction amount of the etching stopper film measured was 0.31 nm.

### [Manufacture of Phase Shift Mask]

Next, a phase shift mask 220 of Example 4 was manufactured through the same procedure as Example 1 using the mask blank 120 of Example 4. Using another mask blank, a phase shift mask was manufactured through the same procedure. In-plane CD uniformity of the phase shift pattern was inspected, obtaining a good result. The cross section of the phase shift pattern was observed using STEM, and verticality of the sidewall of the phase shift pattern was high, digging of the etching stopper film was as slight as about 1 nm, and there was no occurrence of micro trench.

On the phase shift mask (CPL mask) 220 of Example 4, a simulation of a transfer image was made when an exposure transfer was made on a resist film on a semiconductor device at an exposure light of 193 nm wavelength, using AIMS193 (manufactured by Carl Zeiss). The simulated exposure transfer image was inspected, and the design specification was fully satisfied. There was little influence on the exposure transfer caused by the reduction of a transmittance of the transparent portion by providing the etching stopper film 2. It can be considered from this result that a circuit pattern to be finally formed on the semiconductor device can be formed at a high precision, even if the phase shift mask 220 of Example 4 was set on a mask stage of an exposure apparatus and a resist film on the semiconductor device was subjected to an exposure transfer.

### Example 5

### [Manufacture of Mask Blank]

A mask blank 120 of Example 5 was manufactured through the same procedure as the mask blank of Example 1, except for the etching stopper film 2. In Example 5, an etching stopper film 2 including hafnium, aluminum, and oxygen (HfAlO film Hf:Al:O=19.8:16.9:63.3 (atom % ratio)) was applied, which was formed in contact with a surface of the transparent substrate 1 at a thickness of 3 nm. Namely, Hf/[Hf+Al] of the etching stopper film 2 is 0.54. Further, a refractive index n of the etching stopper film 2 to a light of 193 nm wavelength is 2.324, and an extinction coefficient k is 0.069.

A transmittance of an etching stopper film formed on another transparent substrate at a film thickness of 3 nm in a wavelength of an ArF excimer laser (193 nm) was measured using the phase shift measuring apparatus, and a transmittance was 96.3% when a transmittance of the transparent substrate is 100%. From this result, it was found that an influence of reduction in a transmittance caused by providing the etching stopper film of Example 5 is small. Further, a transmittance of an etching stopper film formed on another transparent substrate at a film thickness of 2 nm in a wavelength of an ArF excimer laser (193 nm) was measured using the phase shift measuring apparatus, and a transmittance was 97.9% when a transmittance of the transparent substrate is 100%. The film reduction amount was 1.10 nm in the etching stopper film measured after ten times the cleaning step on the transparent substrate on which the etching stopper film was formed through SC-1 cleaning explained in Example 1.

An etching stopper film formed on another transparent substrate was subjected to dry etching using mixed gas of SF₆ and He as etching gas under the same condition as Example 1, and the film reduction amount of the etching stopper film measured was 0.27 nm.

### [Manufacture of Transfer Mask]

Next, a phase shift mask 220 of Example 5 was manufactured through the same procedure as Example 1 using the mask blank 120 of Example 5.

Using another mask blank, a phase shift mask was manufactured through the same procedure. In-plane CD uniformity of the phase shift pattern was inspected, obtaining a good result. The cross section of the phase shift pattern was observed using STEM, and verticality of the sidewall of the phase shift pattern was high, digging of the etching stopper film was as slight as about 1 nm, and there was no occurrence of micro trench.

On the phase shift mask (CPL mask) 220 of Example 5, a simulation of a transfer image was made when an exposure transfer was made on a resist film on a semiconductor device at an exposure light of 193 nm wavelength, using AIMS193 (manufactured by Carl Zeiss). The simulated exposure transfer image was inspected, and the design specification was fully satisfied. There was little influence on the exposure transfer caused by the reduction of a transmittance of the transparent portion by providing the etching stopper film 2. It can be considered from this result that a circuit pattern to be finally formed on the semiconductor device can be formed at a high precision, even if the phase shift mask 220 of Example 5 was set on a mask stage of an exposure apparatus and a resist film on the semiconductor device was subjected to an exposure transfer.

### Comparative Example 1

### [Manufacture of Mask Blank]

The mask blank of Comparative Example 1 has the same configuration as the mask blank of Example 1, except for the etching stopper film. In Comparative Example 1, an etching stopper film including hafnium and oxygen (HfO film) was formed in contact with a surface of the transparent substrate at a thickness of 3 nm. Concretely, the etching stopper film was formed by placing the transparent substrate in a single-wafer RF sputtering apparatus, and by sputtering (RF sputtering) using HfO₂ target with argon (Ar) gas as sputtering gas. An etching stopper film formed on another transparent substrate under the same conditions was analyzed by X-ray photoelectron spectroscopy, and the result was Hf:Al:O=39.1:0.0:60.9 (atom % ratio). Namely, Hf/[Hf+Al] of the etching stopper film is 1.00. Further, a refractive index n of the etching stopper film to a light of 193 nm wavelength is 2.949, and an extinction coefficient k is 0.274.

A transmittance of an etching stopper film formed on another transparent substrate in a wavelength of an ArF excimer laser (193 nm) was measured using the phase shift measuring apparatus, and a transmittance was 84.2% when a transmittance of the transparent substrate is 100%. A transmittance of an etching stopper film formed on another transparent substrate at a film thickness of 2 nm in a wavelength of an ArF excimer laser (193 nm) was measured using the phase shift measuring apparatus, and a transmittance was 89.8% when a transmittance of the transparent substrate is 100%. The film reduction amount was 0.10 nm in the etching stopper film measured after ten times the cleaning step on the transparent substrate on which the etching stopper film was formed through SC-1 cleaning explained in Example 1.

An etching stopper film formed on another transparent substrate was subjected to dry etching using mixed gas of SF₆ and He as etching gas under the same condition as Example 1, and the film reduction amount of the etching stopper film measured was 0.66 nm, and the influence was not negligible.

### [Manufacture of Phase Shift Mask]

Next, using the mask blank of Comparative Example 1, a phase shift mask of Comparative Example 1 was manufactured through the same procedure as Example 1. On the half tone phase shift mask of Comparative Example 1, a simulation of a transfer image was made when an exposure transfer was made on a resist film on a semiconductor device at an exposure light of 193 nm wavelength, using AIMS193 (manufactured by Carl Zeiss). The simulated exposure transfer image was inspected, and the design specification was not satisfied. A major cause was the reduction of resolution caused by low transmittance of the etching stopper film. It can be understood from this result that when the phase shift mask of Comparative Example 1 was set on a mask stage of an exposure apparatus and exposure-transferred on a resist film on a semiconductor device, frequent generation of short-circuit or disconnection is expected on a circuit pattern to be finally formed on the semiconductor device.

### Comparative Example 2

### [Manufacture of Mask Blank]

The mask blank of Comparative Example 2 has the same configuration as the mask blank of Example 1, except for the etching stopper film. In the etching stopper film of Comparative Example 2, a HfAlO film (Hf:Al:O=35.0:3.7:61.4 (atom % ratio)) including hafnium, aluminum, and oxygen was applied, which was formed in contact with a surface of the transparent substrate at a thickness of 3 nm. Namely, Hf/[Hf+Al] of the etching stopper film is 0.90. Further, a refractive index n of the etching stopper film to a light of 193 nm wavelength is 2.908, and an extinction coefficient k is 0.309.

A transmittance of an etching stopper film formed on another transparent substrate in a wavelength of an ArF excimer laser (193 nm) was measured, and a transmittance was 83.3% when a transmittance of the transparent substrate is 100%. A transmittance of an etching stopper film formed on another transparent substrate at a film thickness of 2 nm in a wavelength of an ArF excimer laser (193 nm) was measured using the phase shift measuring apparatus, and a transmittance was 89.2% when a transmittance of the transparent substrate is 100%. The film reduction amount was 0.20 nm in the etching stopper film measured after ten times the cleaning step on the transparent substrate on which the etching stopper film was formed through SC-1 cleaning explained in Example 1.

An etching stopper film formed on another transparent substrate was subjected to dry etching using mixed gas of SF₆ and He as etching gas, and the film reduction amount of the etching stopper film measured was 0.60 nm, and the influence was not negligible.

### [Manufacture of Phase Shift Mask]

Next, a phase shift mask of Comparative Example 2 was manufactured through the same procedure as Example 1 using the mask blank of Comparative Example 2. On the half tone phase shift mask of Comparative Example 2, a simulation of a transfer image was made when an exposure transfer was made on a resist film on a semiconductor device at an exposure light of 193 nm wavelength, using AIMS193 (manufactured by Carl Zeiss). The simulated exposure transfer image was inspected, and the design specification was not satisfied. A major cause was the reduction of resolution caused by low transmittance of the etching stopper film. It can be understood from this result that when the phase shift mask of Comparative Example 2 was set on a mask stage of an exposure apparatus and exposure-transferred on a resist film on a semiconductor device, frequent generation of short-circuit or disconnection is expected on a circuit pattern to be finally formed on the semiconductor device.

### DESCRIPTION OF REFERENCE NUMERALS

1. transparent substrate
2. etching stopper film
3. phase shift film (thin film for pattern formation)
3a, 3e. phase shift pattern (transfer pattern)
4. light shielding film
4a,4b,4f. light shielding pattern
5, 9, 11, 12. hard mask film
5a,9a,11e,11f,12f. hard mask pattern
6a,7b,10a,17f,18e. resist pattern
8. light shielding film (thin film for pattern formation)
8a. light shielding pattern (transfer pattern)
100,110,120. mask blank
200. transfer mask (phase shift mask)
210. transfer mask (binary mask)
220. transfer mask (CPL mask)

1. A mask blank comprising:
a transparent substrate;
an etching stopper film provided on the transparent substrate and containing hafnium, aluminum, and oxygen; and
a thin film for pattern formation provided on the etching stopper film and containing silicon,
wherein a ratio by atom % of an amount of the hafnium in the etching stopper film to a total amount of the hafnium and the aluminum in the etching stopper film is 0.86 or less.

2. The mask blank according to claim 1, wherein a ratio by atom % of an amount of the hafnium in the etching stopper film to a total amount of the hafnium and the aluminum in the etching stopper film is 0.60 or more.

3. The mask blank according to claim 1, wherein an oxygen content of the etching stopper film is 60 atom % or more.

4. The mask blank according to claim 1, wherein the etching stopper film has an amorphous structure in a state comprising a bond of hafnium and oxygen and a bond of aluminum and oxygen.

5. The mask blank according to claim 1, wherein the etching stopper film consists of hafnium, aluminum, and oxygen.

6. The mask blank according to claim 1, wherein the etching stopper film is formed in contact with a main surface of the transparent substrate.

7. The mask blank according to claim 1, wherein a thickness of the etching stopper film is 2 nm or more.

8. The mask blank according to claim 1, wherein the thin film is a phase shift film configured to transmit an exposure light so that the transmitted light has a phase difference of 150 degrees or more and 210 degrees or less with respect to the exposure light transmitted through air for a same distance as a thickness of the phase shift film.

9. The mask blank according to claim 8, wherein a light shielding film is provided on the phase shift film.

10. The mask blank according to claim 9, wherein the light shielding film contains chromium.

11. A transfer mask comprising:
a transparent substrate;
an etching stopper film provided on the transparent substrate and containing hafnium, aluminum, and oxygen; and
a thin film having a transfer pattern, provided on the etching stopper film, and containing silicon,
wherein a ratio by atom % of an amount of the hafnium in the etching stopper film to a total amount of the hafnium and the aluminum in the etching stopper film is 0.86 or less.

12. The transfer mask according to claim 11, wherein a ratio by atom % of an amount of the hafnium in the etching stopper film to a total amount of the hafnium and the aluminum in the etching stopper film is 0.60 or more.

13. The transfer mask according to claim 11, wherein an oxygen content of the etching stopper film is 60 atom % or more.

14. The transfer mask according to claim 11, wherein the etching stopper film has an amorphous structure in a state including a bond of hafnium and oxygen and a bond of aluminum and oxygen.

15. The transfer mask according to claim 11, wherein the etching stopper film consists of hafnium, aluminum, and oxygen.

16. The transfer mask according to claim 11, wherein the etching stopper film is formed in contact with a main surface of the transparent substrate.

17. The transfer mask according to claim 11, wherein a thickness of the etching stopper film is 2 nm or more.

18. The transfer mask according to claim 11, wherein the thin film is a phase shift film configured to transmit an exposure light so that the transmitted light has a phase difference of 150 degrees or more and 210 degrees or less with respect to the exposure light transmitted through air for a same distance as a thickness of the phase shift film.

19. The transfer mask according to claim 18 comprising a light shielding film having a light shielding pattern with a light shielding band on the phase shift film.

20. The transfer mask according to claim 19, wherein the light shielding film contains chromium.

21. A method of manufacturing a semiconductor device comprising using the transfer mask according to claim 11 to exposure-transfer the pattern on the transfer mask to a resist film on a semiconductor substrate.
